(19) United States
(12) Patent Application Publication
(10) Pub. No.: US 2026/0271702 A1
(43) Pub. Date: Sep. 10, 2026

(54) POWER PICKUP FOR DUAL SIDE POWER STRUCTURE

(71) Applicant: Taiwan Semiconductor Manufacturing Company, Ltd., Hsinchu (TW)

(72) Inventors: Ching-Yu HUANG, Hsinchu City (TW); Wei-Cheng LIN, Taichung City (TW); Jiann-Tyng TZENG, Hsinchu (TW)

(21) Appl. No.: 19/071,004

(22) Filed: Mar. 5, 2025

Related U.S. Application Data
(60) Provisional application No. 63/712,848, filed on Oct. 28, 2024.

(51) Int. Cl. H10W 20/41; H10W 20/00; H10W 20/42; H10W 90/00

(52) U.S. Cl. CPC H10W 20/435; H10W 20/023; H10W 20/42; H10W 20/427; H10W 90/00

(57) ABSTRACT

An integrated circuit includes a substrate having a front side and a back side that is opposite the front side. The substrate includes at least one active region on the front side. A circuit is situated on the front side of the substrate and a front side metallization layer is disposed over the circuit. A back side metallization layer is disposed under the back side of the substrate and a first power pickup is situated on a first side of the circuit. The first power pickup is configured to deliver one or more voltages from the back side metallization layer, that is electrically coupled to the at least one active region, to the front side metallization layer.

### BACKGROUND

Typically, an integrated circuit includes a power delivery or power distribution network (PDN) for delivering power to components in the integrated circuit. Some integrated circuits include frontside PDNs with frontside conductive traces for delivering power and some integrated circuits include backside PDNs with backside conductive traces for delivering power. A backside PDN may be referred to as a “super power rail” (SPR). Also, some integrated circuits include dual-side power rail structures that include both frontside and backside PDNs. A dual-side power rail structure can reduce the area of an integrated circuit and reduce source resistances from power sources to the components of the integrated circuit due to shunted frontside and backside power, which results in improvements in circuit speeds.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. In addition, the drawings are illustrative as examples of embodiments of the disclosure and are not intended to be limiting.

FIG. 1 is a diagram schematically illustrating a device that includes an electrical circuit, such as a clock cell or clock circuit, and a power pickup cell or circuit, in accordance with some embodiments.

FIG. 2 is a diagram schematically illustrating a clock cell and a power pickup cell that is situated along one side of the clock cell, in accordance with some embodiments.

FIG. 3 is a diagram schematically illustrating a clock cell, and a first power pickup cell and a second power pickup cell situated along opposing sides of the clock cell, in accordance with some embodiments.

FIG. 4 is a diagram schematically illustrating a clock cell, and a first power pickup cell and a second power pickup cell that are longer than the clock cell, in accordance with some embodiments.

FIG. 5 is a diagram schematically illustrating a clock cell, and a first power pickup cell and a second power pickup cell that are on the short sides of the clock cell, in accordance with some embodiments.

FIG. 6 is a diagram schematically illustrating a clock cell, and a first power pickup cell and a second power pickup cell that are on the short sides of the clock cell, in accordance with some embodiments.

FIG. 7 is a diagram schematically illustrating a clock cell and a power pickup cell that surrounds the clock cell on all sides of the clock cell, in accordance with some embodiments.

FIG. 8 is a diagram schematically illustrating circuit options that include a reference circuit, a one-sided power pickup cell circuit, and a dual-sided or two-sided power pickup cell circuit, in accordance with some embodiments.

FIG. 9 is a diagram schematically illustrating a device that includes a substrate that includes N-type well active regions for power source voltage VDD and P-type well active regions for power source voltage VSS, in accordance with some embodiments.

FIG. 10 includes diagrams schematically illustrating the device of FIG. 9 including a VB type power pickup structure, first frontside metallization layers M0, and first backside metallization layers BM0, in accordance with some embodiments.

FIG. 11 is a diagram schematically illustrating a cross-section of the device of FIG. 10 taken along the line A-A in FIG. 10, in accordance with some embodiments.

FIG. 12 is a diagram schematically illustrating a device that includes a clock cell situated next to or adjacent power pickup cells, in accordance with some embodiments.

FIG. 13 is a diagram schematically illustrating a cross-section of a VDD power pickup cell taken along the line B-B in FIG. 12, in accordance with some embodiments.

FIG. 14 is a diagram schematically illustrating a device that includes an FTV power pickup structure, first frontside metallization layers M0, and first backside metallization layers BM0 for delivering power source voltage VDD, in accordance with some embodiments.

FIG. 15 is a diagram schematically illustrating a cross-section of the device of FIG. 14 taken along the line C-C in FIG. 14, in accordance with some embodiments.

FIG. 16 is a diagram schematically illustrating a device that includes an FTV power pickup structure, first frontside metallization layers M0, and first backside metallization layers BM0 for delivering power source voltage VSS, in accordance with some embodiments.

FIG. 17 is a diagram schematically illustrating a cross-section of the device of FIG. 16 taken along the line D-D in FIG. 16, in accordance with some embodiments.

FIG. 18 is a diagram schematically illustrating a device that includes an FTV power pickup structure, first frontside metallization layers M0, and first backside metallization layers BM0 for delivering power source voltage VDD, in accordance with some embodiments.

FIG. 19 is a diagram schematically illustrating a cross-section of the device of FIG. 18 taken along the line E-E in FIG. 18, in accordance with some embodiments.

FIG. 20 is a diagram schematically illustrating a device that includes an FTV power pickup structure, first frontside metallization layers M0, and first backside metallization layers BM0 for delivering power source voltage VSS, in accordance with some embodiments.

FIG. 21 is a diagram schematically illustrating a cross-section of the device of FIG. 20 taken along the line F-F in FIG. 20, in accordance with some embodiments.

FIG. 22 is a diagram illustrating characteristics for a VB type power pickup cell and an FTV type power pickup cell, in accordance with some embodiments.

FIG. 23 is a diagram schematically illustrating a device that includes a clock cell and a power pickup cell that surrounds the clock cell on all sides of the clock cell, in accordance with some embodiments.

FIG. 24 is a diagram schematically illustrating a method of manufacturing an integrated circuit, in accordance with some embodiments.

FIG. 25 is a block diagram schematically illustrating an example of a computer system configured to provide the devices, including electronic devices and semiconductor devices, and methods of the current disclosure, in accordance with some embodiments.

FIG. 26 is a block diagram of a semiconductor device manufacturing system and a semiconductor device manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In circuits with dual-side power rail structures, power voltage drops between the frontside PDN and the backside PDN degrade performance due to uneven power distribution and high-resistance power pickup cells or circuits. For example, frontside to backside power pickup cells formed in metal-over-diffusion (MD) and epitaxial layers increase resistance.

Disclosed embodiments include pickup cells or circuits that reduce current-resistance (IR) voltage drops and improve routing resources. Disclosed embodiments include different types of power pickup structures, such as backside via (VB) pickup structures and feed-through-via (FTV) pickup structures. Disclosed embodiments further include different placements of the pickup cells or structures next to a circuit or cell, such as a clock cell. In some embodiments, the power pickup cells are situated on or along one side of the circuit. In some embodiments, the power pickup cells are situated on or along two opposing sides of the circuit. In some embodiments, the power pickup cells are situated on all sides of the circuit.

Disclosed embodiments include an integrated circuit that includes a substrate with at least one active region and a circuit situated on the front side of the substrate. A front side metallization layer is disposed over the circuit and a back side metallization layer, that is electrically coupled to the at least one active region, is disposed under the back side of the substrate. A first power pickup is situated on a first side of the circuit and configured to deliver one or more voltages from the back side metallization layer to the front side metallization layer. In some embodiments, the integrated circuit includes a second power pickup situated on a second side of the circuit that is opposite the first side of the circuit and configured to deliver the one or more voltages from the back side metallization layer to the front side metallization layer.

In some embodiments, the integrated circuit includes a VB, an epitaxial layer, an MD contact, and a via-to-drain (VDR) contact, where the back side metallization layer is electrically connected to the VB that is electrically connected to the epitaxial layer that is electrically connected to the MD contact that is electrically connected to the VDR contact that is electrically connected to the front side metallization layer. Such that a voltage is conducted between the back side metallization layer and the front side metallization layer through the VB, the epitaxial layer, the MD contact, and the VDR contact. In some embodiments, the integrated circuit includes an FTV, an MD contact, and a VDR contact, where the back side metallization layer is electrically connected to the FTV that is electrically connected to the MD contact that is electrically connected to the VDR contact that is electrically connected to the front side metallization layer. Such that a voltage is conducted between the back side metallization layer and the front side metallization layer through the FTV, the MD contact, and the VDR contact. Where, the MD contact is also electrically connected to an epitaxial layer.

Disclosed embodiments further include a device that includes a circuit situated on a front side of a substrate, a front side metallization layer disposed over the substrate, and a back side metallization layer disposed under the back side of the substrate. A power pickup is situated on a side of the circuit. The power pickup includes an FTV, an MD contact, and a VDR contact that is electrically connected from the back side metallization layer to the front side metallization layer. Where, the MD contact is situated between epitaxial layers and not electrically connected to the epitaxial layers.

Still further disclosed embodiments include a method of manufacturing an integrated circuit that includes forming a substrate having a front side and a back side that is opposite the front side; forming active regions on the front side of the substrate; forming a circuit on the front side of the substrate; forming a front side metallization layer over the circuit; forming a back side metallization layer under the back side of the substrate and electrically coupled to at least one active region of the active regions; and forming a power pickup on a side of the circuit to deliver one or more voltages from the back side metallization layer to the front side metallization layer.

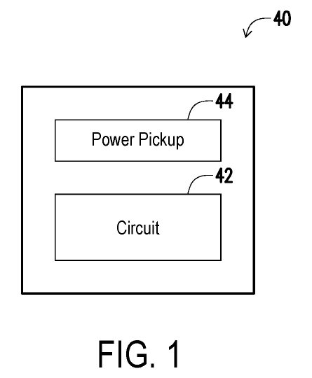

FIG. 1 is a diagram schematically illustrating a device 40, in accordance with some embodiments. The device 40 includes an electrical circuit 42, such as a clock cell or clock circuit, and a power pickup cell or circuit 44. In some embodiments, the device 40 includes multiple electrical circuits 42. In some embodiments, the device 40 includes multiple power pickup cells 44. In some embodiments, each of the electrical circuits 42 includes transistors, diodes, resistors, and/or other circuit elements that make up an electrical circuit. In some embodiments, the device 40 includes one or more semiconductors. In some embodiments, the device 40 includes one or more integrated circuits.

In different layouts, the device 40 can include different placements of the power pickup cell 44 in relation to the electrical circuit 42. In some embodiments, the power pickup cell 44 is situated on or along one side of the electrical circuit 42. In some embodiments, power pickup cells 44 are situated on or along two opposing sides of the electrical circuit 42. In some embodiments, power pickup cells 44 are situated on all sides of the electrical circuit 42.

The power pickup cell 44 is configured to deliver one or more voltages, such as power source voltages VDD and VSS, from a back side of the device 40 to a front side of the device 40. The power pickup cell 44 reduces wire lengths from the power sources to the electrical circuit 42. Also, the power pickup cell 44 reduces IR voltage drops from the power sources to the electrical circuit 42 and improves routing resources. In some embodiments, the power pickup cell 44 is attached to the electrical circuit 42. In some embodiments, the power pickup cell 44 is nearby the electrical circuit 42.

The power pickup cell 44 can include different types of power pickup structures. In some embodiments, the power pickup cell 44 includes VB pickup structures. In some embodiments, the power pickup cell 44 includes FTV pickup structures.

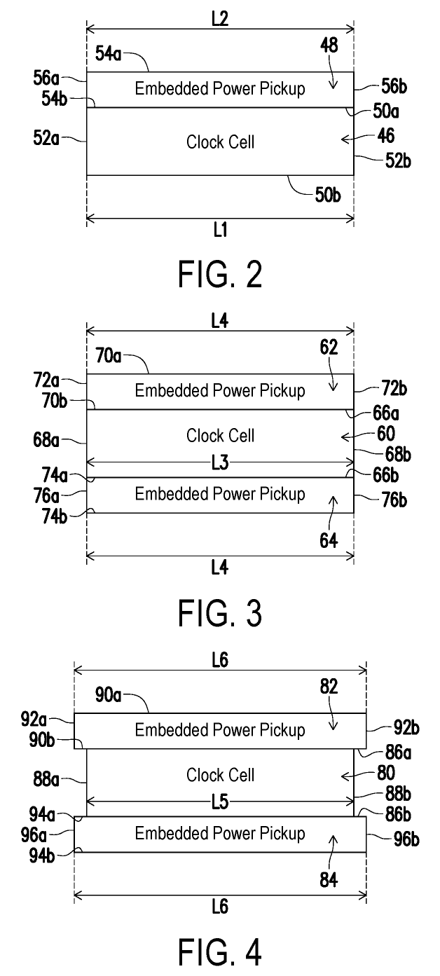

FIG. 2 is a diagram schematically illustrating a clock cell 46 and a power pickup cell 48 that is situated along one side of the clock cell 46, in accordance with some embodiments. The power pickup cell 48 is embedded in a device, such as the device 40 of FIG. 1, and the clock cell 46 is situated on a front side of the device. In some embodiments, the clock cell 46 is like the electrical circuit 42 (shown in FIG. 1). In some embodiments, the power pickup cell 48 is like the power pickup cell 44 (shown in FIG. 1).

The clock cell 46 has a length L1 and the power pickup cell 48 has a length L2 that is the same as the length L1 of the clock cell 46. The clock cell 46 includes two long sides 50a and 50b and two short sides 52a and 52b, and the power pickup cell 48 includes two long sides 54a and 54b and two short sides 56a and 56b. The power pickup cell 48 has the long side 54b situated next to or adjacent the long side 50a of the clock cell 46. In other embodiments, the power pickup cell 48 has the long side 54a situated next to or adjacent the long side 50b of the clock cell 46. In some embodiments, the power pickup cell 48 must be at least as long as the clock cell 46.

The power pickup cell 48 is configured to deliver one or more voltages, such as power source voltages VDD and VSS, from the back side of the device to the front side of the device. In some embodiments, the power pickup cell 48 is attached to the clock cell 46. In other embodiments, the power pickup cell 48 is nearby the clock cell 46. Also, in some embodiments, the power pickup cell 48 is configured to deliver the one or more voltages to the clock cell 46.

The power pickup cell 48 reduces wire lengths from the power source to the clock cell 46. Also, the power pickup cell 44 reduces IR voltage drops from the power source to the clock cell 46 and improves routing resources.

FIG. 3 is a diagram schematically illustrating a clock cell 60 and a first power pickup cell 62 and a second power pickup cell 64 situated along two sides of the clock cell 60, in accordance with some embodiments. The first power pickup cell 62 is situated along a first side of the clock cell 60, and the second power pickup cell 64 is situated along a second side of the clock cell 60. The first side of the clock cell 60 opposes the second side of the clock cell 60.

Each of the first and second power pickup cells 62 and 64 is embedded in a device, such as the device 40 of FIG. 1, and the clock cell 60 is situated on a front side of the device. In some embodiments, the clock cell 60 is like the electrical circuit 42 (shown in FIG. 1). In some embodiments, each of the first and second power pickup cells 62 and 64 is like the power pickup cell 44 (shown in FIG. 1).

The clock cell 60 has a length L3 and each of the first and second power pickup cells 62 and 64 has a length L4 that is the same as the length L3 of the clock cell 60. The clock cell 60 includes two long sides 66a and 66b and two short sides 68a and 68b. The first power pickup cell 62 includes two long sides 70a and 70b and two short sides 72a and 72b, and the second power pickup cell 64 includes two long sides 74a and 74b and two short sides 76a and 76b. The first power pickup cell 62 has the long side 70b situated next to or adjacent the long side 66a of the clock cell 60, and the second power pickup cell 64 has the long side 74a situated next to or adjacent the long side 66b of the clock cell 60. In some embodiments, each of the first and second power pickup cells 62 and 64 must be at least as long as the clock cell 60.

Each of the power pickup cells 62 and 64 is configured to deliver one or more voltages, such as power source voltages VDD and VSS, from the back side of the device to the front side of the device. In some embodiments, one or more of the first and second power pickup cells 62 and 64 is attached to the clock cell 60. In some embodiments, one or more of the first and second power pickup cells 62 and 64 is nearby the clock cell 60. Also, in some embodiments, one or more of the first and second power pickup cells 62 and 64 is configured to deliver the one or more voltages to the clock cell 60.

The power pickup cells 62 and 64 reduce wire lengths from the power sources to the clock cell 60. Also, the power pickup cells 62 and 64 reduce IR voltage drops from the power sources to the clock cell 60 and improve routing resources.

FIG. 4 is a diagram schematically illustrating a clock cell 80 and a first power pickup cell 82 and a second power pickup cell 84 that are longer than the clock cell 80, in accordance with some embodiments. The first power pickup cell 82 is situated along a first side of the clock cell 80, and the second power pickup cell 84 is situated along a second side of the clock cell 80. The first side of the clock cell 80 opposes the second side of the clock cell 80.

Each of the first and second power pickup cells 82 and 84 is embedded in a device, such as the device 40 of FIG. 1, and the clock cell 80 is situated on a front side of the device. In some embodiments, the clock cell 80 is like the electrical circuit 42 (shown in FIG. 1). In some embodiments, each of the first and second power pickup cells 82 and 84 is like the power pickup cell 44 (shown in FIG. 1).

The clock cell 80 has a length L5 and each of the first and second power pickup cells 82 and 84 has a length L6 that is greater than the length L5 of the clock cell 80. The clock cell 80 includes two long sides 86a and 86b and two short sides 88a and 88b. The first power pickup cell 82 includes two long sides 90a and 90b and two short sides 92a and 92b, and the second power pickup cell 84 includes two long sides 94a and 94b and two short sides 96a and 96b. The first power pickup cell 82 has the long side 90b situated next to or adjacent the long side 86a of the clock cell 80, and the second power pickup cell 84 has the long side 94a situated next to or adjacent the long side 86b of the clock cell 80.

Each of the power pickup cells 82 and 84 is configured to deliver one or more voltages, such as power source voltages VDD and VSS, from the back side of the device to the front side of the device. In some embodiments, one or more of the first and second power pickup cells 82 and 84 is attached to the clock cell 80. In some embodiments, one or more of the first and second power pickup cells 82 and 84 is nearby the clock cell 80. Also, in some embodiments, one or more of the first and second power pickup cells 82 and 84 is configured to deliver the one or more voltages to the clock cell 80.

The power pickup cells 82 and 84 reduce wire lengths from the power sources to the clock cell 80. Also, the power pickup cells 82 and 84 reduce IR voltage drops from the power sources to the clock cell 80 and improve routing resources.

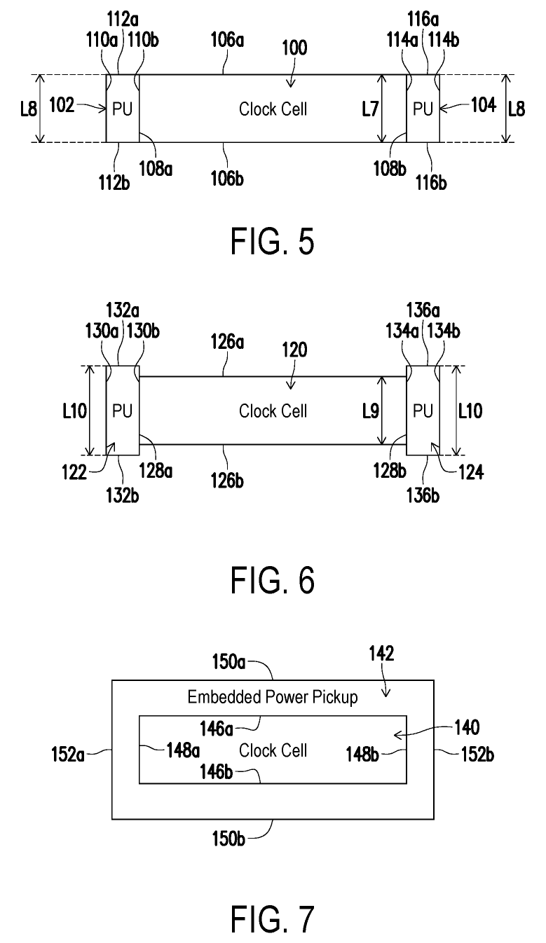

FIG. 5 is a diagram schematically illustrating a clock cell 100, and a first power pickup cell 102 and a second power pickup cell 104 that are along the short sides of the clock cell 100, in accordance with some embodiments. The first power pickup cell 102 is situated along a first side of the clock cell 100, and the second power pickup cell 104 is situated along a second side of the clock cell 100. The first side of the clock cell 100 opposes the second side of the clock cell 100.

Each of the first and second power pickup cells 102 and 104 is embedded in a device, such as the device 40 of FIG. 1, and the clock cell 100 is situated on a front side of the device. In some embodiments, the clock cell 100 is like the electrical circuit 42 (shown in FIG. 1). In some embodiments, each of the first and second power pickup cells 102 and 104 is like the power pickup cell 44 (shown in FIG. 1).

The clock cell 100 has a short side length L7 and each of the first and second power pickup cells 102 and 104 has a long side length L8 that is the same as the length L7 of the clock cell 100. The clock cell 100 includes two long sides 106a and 106b and two short sides 108a and 108b. The first power pickup cell 102 includes two long sides 110a and 110b and two short sides 112a and 112b, and the second power pickup cell 104 includes two long sides 114a and 114b and two short sides 116a and 116b. The first power pickup cell 102 has the long side 110b situated next to or adjacent the short side 108a of the clock cell 100, and the second power pickup cell 104 has the long side 114a situated next to or adjacent the short side 108b of the clock cell 100. In some embodiments, each of the long sides of the first and second power pickup cells 102 and 104 must be at least as long as the short sides of the clock cell 100.

Each of the power pickup cells 102 and 104 is configured to deliver one or more voltages, such as power source voltages VDD and VSS, from the back side of the device to the front side of the device. In some embodiments, one or more of the first and second power pickup cells 102 and 104 is attached to the clock cell 100. In some embodiments, one or more of the first and second power pickup cells 102 and 104 is nearby the clock cell 100. Also, in some embodiments, one or more of the first and second power pickup cells 102 and 104 is configured to deliver the one or more voltages to the clock cell 100.

The power pickup cells 102 and 104 reduce wire lengths from the power sources to the clock cell 100. Also, the power pickup cells 102 and 104 reduce IR voltage drops from the power sources to the clock cell 100 and improve routing resources.

FIG. 6 is a diagram schematically illustrating a clock cell 120, and a first power pickup cell 122 and a second power pickup cell 124 that are along the short sides of the clock cell 120, in accordance with some embodiments. The first power pickup cell 122 is situated along a first short side of the clock cell 120, and the second power pickup cell 124 is situated along a second short side of the clock cell 120. The first short side of the clock cell 120 opposes the second short side of the clock cell 120.

Each of the first and second power pickup cells 122 and 124 is embedded in a device, such as the device 40 of FIG. 1, and the clock cell 120 is situated on a front side of the device. In some embodiments, the clock cell 120 is like the electrical circuit 42 (shown in FIG. 1). In some embodiments, each of the first and second power pickup cells 122 and 124 is like the power pickup cell 44 (shown in FIG. 1).

The clock cell 120 has a short side length L9 and each of the first and second power pickup cells 122 and 124 has a long side length L10 that is longer than the short side length L9 of the clock cell 120. The clock cell 120 includes two long sides 126a and 126b and two short sides 128a and 128b. The first power pickup cell 122 includes two long sides 130a and 130b and two short sides 132a and 132b, and the second power pickup cell 124 includes two long sides 134a and 134b and two short sides 136a and 136b. The first power pickup cell 122 has the long side 130b situated next to or adjacent the short side 128a of the clock cell 120, and the second power pickup cell 124 has the long side 134a situated next to or adjacent the short side 128b of the clock cell 120.

Each of the power pickup cells 122 and 124 is configured to deliver one or more voltages, such as power source voltages VDD and VSS, from the back side of the device to the front side of the device. In some embodiments, one or more of the first and second power pickup cells 122 and 124 is attached to the clock cell 120. In some embodiments, one or more of the first and second power pickup cells 122 and 124 is nearby the clock cell 120. Also, in some embodiments, one or more of the first and second power pickup cells 122 and 124 is configured to deliver the one or more voltages to the clock cell 120.

The power pickup cells 122 and 124 reduce wire lengths from the power sources to the clock cell 120. Also, the power pickup cells 122 and 124 reduce IR voltage drops from the power sources to the clock cell 120 and improve routing resources.

FIG. 7 is a diagram schematically illustrating a clock cell 140 and a power pickup cell 142 that surrounds the clock cell 140 on all sides of the clock cell 140, in accordance with some embodiments. The power pickup cell 142 is embedded in a device, such as the device 40 of FIG. 1, and the clock cell 140 is situated on a front side of the device. In some embodiments, the clock cell 140 is like the electrical circuit 42 (shown in FIG. 1). In some embodiments, the power pickup cell 142 is like the power pickup cell 44 (shown in FIG. 1).

The clock cell 140 includes two long sides 146a and 146b and two short sides 148a and 148b, and the power pickup cell 142 includes two long sides 150a and 150b and two short sides 152a and 152b. The power pickup cell 142 is configured to deliver one or more voltages, such as power source voltages VDD and VSS, from the back side of the device to the front side of the device. In some embodiments, the power pickup cell 142 is attached to the clock cell 140 along the two long sides 146a and 146b and the two short sides 148a and 148b of the clock cell 140. In some embodiments, the power pickup cell 142 is nearby the clock cell 140 along the two long sides 146a and 146b and the two short sides 148a and 148b of the clock cell 140. Also, in some embodiments, the power pickup cell 142 is configured to deliver the one or more voltages to the clock cell 140.

The power pickup cell 142 reduces wire lengths from the power sources to the clock cell 140. Also, the power pickup cell 142 reduces IR voltage drops from the power sources to the clock cell 140 and improves routing resources.

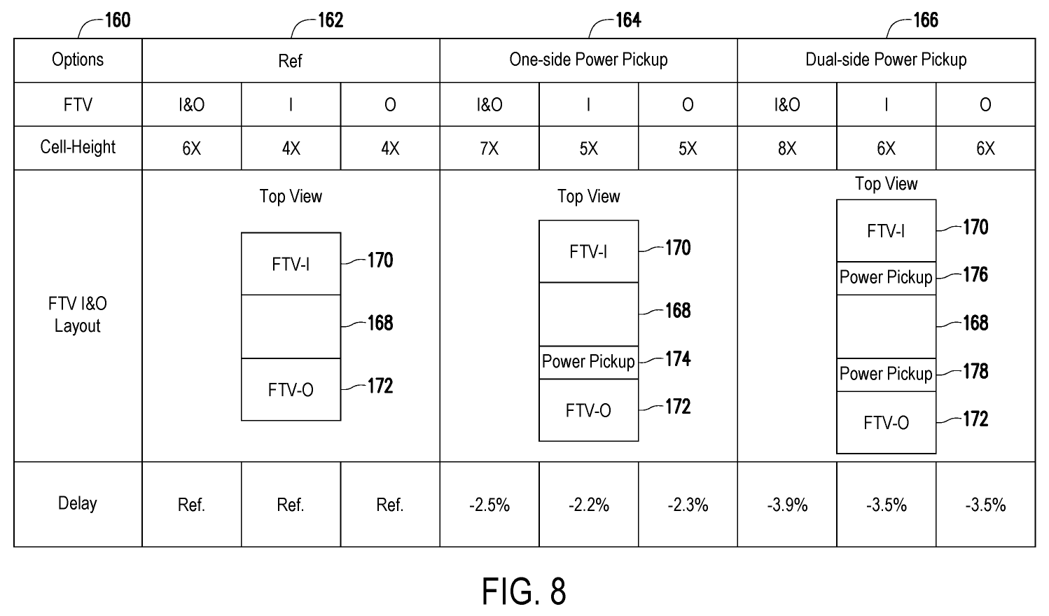

FIG. 8 is a diagram schematically illustrating circuit options 160, in accordance with some embodiments. The circuit options 160 include a reference circuit 162, a one-sided power pickup cell circuit 164, and a dual-sided or two-sided power pickup cell circuit 166. Each of the reference circuit 162, the one-sided power pickup cell circuit 164, and the dual-sided power pickup cell circuit 166 includes an electrical circuit 168, such as a clock cell, an FTV input (FTV-I) 170 and an FTV output (FTV-O) 172.

The reference circuit 162 includes the electrical circuit 168 with the FTV-I 170 on one side and the FTV-O 172 on another side that opposes the one side. The reference circuit 162 has an input/output (I&O) cell-height of 6X, an input (I) cell-height of 4X, and an output (O) cell-height of 4X. The delay with wire is at a reference value.

The one-sided power pickup cell circuit 164 includes a power pickup cell 174 situated between the electrical circuit 168 and the FTV-O 172. The one-sided power pickup cell circuit 164 has an I&O cell-height of 7X, a I cell-height of 5X, and an O cell-height of 5X. The I&O delay is at -2.5% of the reference value, the I delay is at -2.2% of the reference value, and the O delay is at -2.3% of the reference value. In other embodiments, the power pickup cell circuit 174 can be situated between the electrical circuit 168 and the FTV-I 170.

The dual-sided power pickup cell circuit 166 includes a first power pickup cell 176 situated between the electrical circuit 168 and the FTV-I 170 and a second power pickup cell circuit 178 between the electrical circuit 168 and the FTV-O 172. The dual-sided power pickup cell circuit 166 has an I&O cell-height of 8X, a I cell-height of 6X, and an O cell-height of 6X. The I&O delay is at -3.9% of the reference value, the I delay is at -3.5% of the reference value, and the O delay is at -3.5% of the reference value.

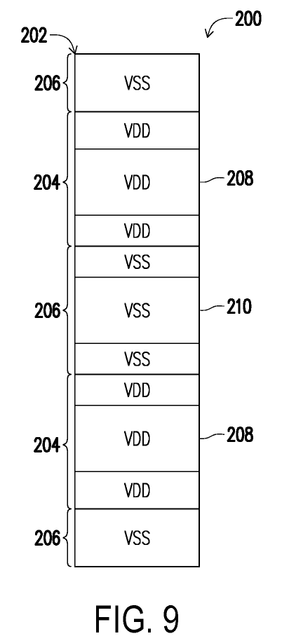

FIG. 9 is a diagram schematically illustrating a top view of a device 200, in accordance with some embodiments. The device 200 includes a substrate 202 that includes N-type well active regions 204 for power source voltage VDD and P-type well active regions 206 for power source voltage VSS. The device 200 includes backside metallization layers 208 for delivering the power source VDD and backside metallization layer 210 for delivering the power source VSS. In some embodiments, the device 200 is like the device 40 of FIG. 1.

The power source VDD is delivered from the backside metallization layers 208 through power pickup cells to electrical circuits in the device 200. The power source VSS is delivered from the backside metallization layer 210 through one or more power pickup cells to the electrical circuits in the device 200. In some embodiments, each of the electrical circuits is like the electrical circuit 42 (shown in FIG. 1). In some embodiments, each of the power pickup cells is like the power pickup cell 44 (shown in FIG. 1). In some embodiments, the electrical circuits are clock cells.

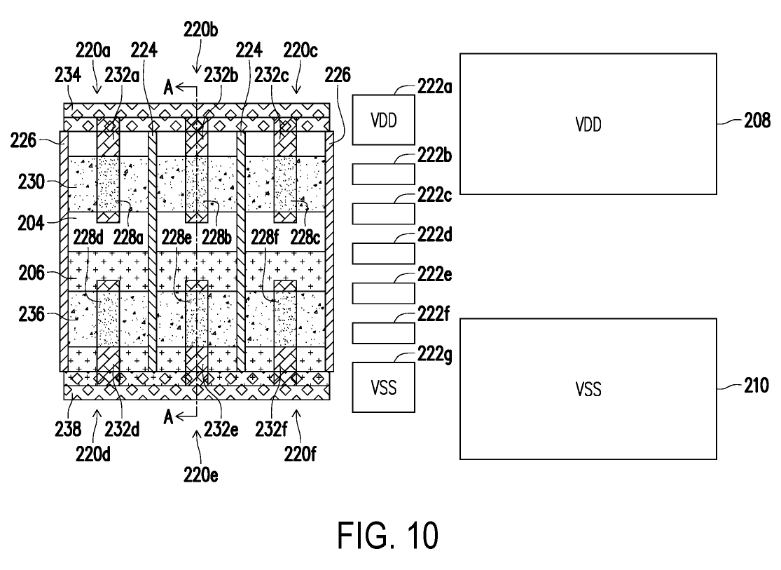

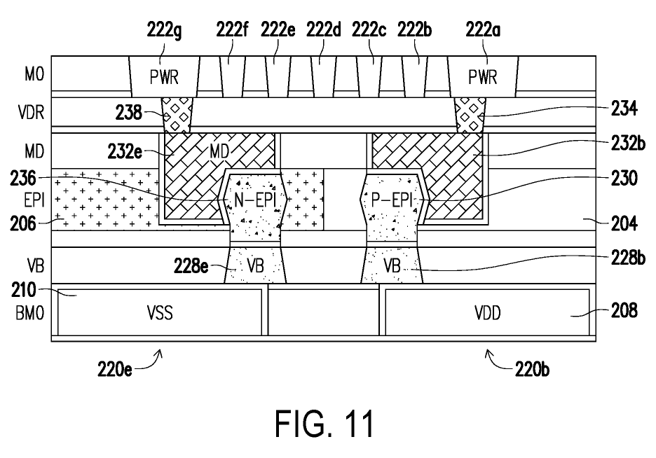

FIGS. 10 and 11 are diagrams schematically illustrating the device 200 of FIG. 9 including VB type power pickup cells or structures 220a-220f for delivering the power source VDD and the power source VSS from the back side of the device 200 to the front side of the device 200. The VB type power pickup structures 220a-220f simultaneously deliver the power source VDD and the power source VSS from the back side of the device 200 to the front side of the device 200. In some embodiments, the device 200 is like the device 40 of FIG. 1.

FIG. 10 includes diagrams schematically illustrating top views of the VB type power pickup structures 220a-220f, first frontside metallization layers M0222a-222g, and the first backside metallization layers BM0208 and 210 (shown in FIG. 9), in accordance with some embodiments. The first frontside metallization layers M0222a-222g are above or on top of the VB type power pickup structures 220a-220f, and the first backside metallization layers BM0 208 and 210 are below or underneath the VB type power pickup structures 220a-220f. The power distribution networks in the first frontside metallization layers M0222a-222g are different for the power source VDD and the power source VSS. Also, the device 200 includes gate contacts 224, such as polysilicon (PO) gates or lines, and edge fingers 226, such as edge PO fingers. The first frontside metallization layers M0222a-222g and the first backside metallization layers BM0208 and 210 are drawn separately for clarity.

The VB type power pickup structures 220a-220c pass through the N-type well active region 204 for the power source voltage VDD, and the VB type power pickup structures 220d-220f pass through the P-type well active region 206 for the power source voltage VSS.

Each of the VB type power pickup structures 220a-220c includes a VB contact 228a-228c, P-type epitaxial layer active region 230, an MD contact 232a-232c, and VDR contact 234. The first backside metallization layer BM0 208 is electrically connected to and delivers power source VDD to the VB contacts 228a-228c that are electrically connected to the P-type epitaxial layer active region 230 that is electrically connected to the MD contacts 232a-232c that are electrically connected to the VDR contact 234 that is electrically connected to the first frontside metallization layer M0222a for the power source VDD.

Each of the VB type power pickup structures 220d-220f includes a VB contact 228d-228f, N-type epitaxial layer active region 236, an MD contact 232d-232f, and VDR contact 238. The first backside metallization layer BM0210 is electrically connected to and delivers power source VSS to the VB contacts 228d-228f that are electrically connected to the N-type epitaxial layer active region 236 that is electrically connected to the MD contacts 232d-232f that are electrically connected to the VDR contact 238 that is electrically connected to the first frontside metallization layer M0222g for the power source VSS.

FIG. 11 is a diagram schematically illustrating a cross-section of the device 200 taken along the line A-A in FIG. 10, in accordance with some embodiments. The device 200 includes the first frontside metallization layers M0222a-222g above or on top of the VB type power pickup structures 220b and 220e, and the first backside metallization layers BM0208 and 210 below or underneath the VB type power pickup structures 220b and 220e.

The VB type power pickup structure 220b passes through the N-type well active region 204 for the power source voltage VDD, and the VB type power pickup structure 220e passes through the P-type well active region 206 for the power source voltage VSS.

The VB type power pickup structure 220b includes the VB contact 228b, the P-type epitaxial layer active region 230, the MD contact 232b, and the VDR contact 234. The first backside metallization layer BM0208 is electrically connected to and delivers power source VDD to the VB contact 228b that is electrically connected to the P-type epitaxial layer active region 230 that is electrically connected to the MD contact 232b that is electrically connected to the VDR contact 234 that is electrically connected to the first frontside metallization layer M0222a for the power source VDD. The power source voltage VDD flows from the first backside metallization layer BM0208 to the VB contact 228b to the P-type epitaxial layer active region 230 to the MD contact 232b to the VDR contact 234 and to the first frontside metallization layer M0222a and, in some embodiments, to a VDD distribution network.

The VB type power pickup structure 220e includes the VB contact 228e, the N-type epitaxial layer active region 236, the MD contact 232e, and the VDR contact 238. The first backside metallization layer BM0 210 is electrically connected to and delivers power source VSS to the VB contact 228e that is electrically connected to the N-type epitaxial layer active region 236 that is electrically connected to the MD contact 232e that is electrically connected to the VDR contact 238 that is electrically connected to the first frontside metallization layer M0222g for the power source VSS. The power source voltage VSS flows to or from the first backside metallization layer BM0210 to the VB contact 228e to the N-type epitaxial layer active region 236 to the MD contact 232e to the VDR contact 238 to the first frontside metallization layer M0222g and, in some embodiments, to a VSS distribution network.

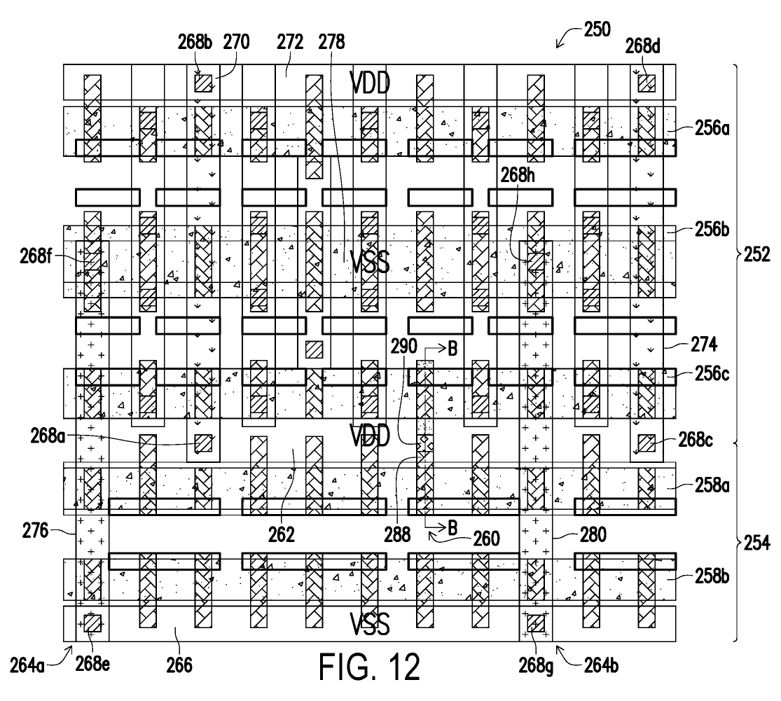

FIG. 12 is a diagram schematically illustrating a device 250 that includes a clock cell 252 situated next to or adjacent power pickup cells 254, in accordance with some embodiments. The clock cell 252 is situated on the front side of the device 250 and the power pickup cells 254 deliver power source voltages VDD and VSS from the back side of the device 250 to the front side of the device 250 and the clock cell 252. The clock cell 252 includes epitaxial active regions 256a-256c and the power pickup cells 254 include epitaxial active regions 258a and 258b.

The power pickup cells 254 include a VDD power pickup cell 260 that delivers power source voltage VDD from the back side of the device 250 to the front side of the device 250 and to the clock cell 252. The VDD power pickup cell 260 is a VB type power pickup cell that delivers power source voltage VDD to a first metallization layer M0 that is VDD power rail 262.

The power pickup cells 254 include VSS power pickup cells 264a and 264b that deliver power source voltage VSS from the back side of the device 250 to the front side of the device 250 and the clock cell 252. The VSS power pickup cells 264a and 264b deliver power source voltage VSS to a first metallization layer M0 that is VSS power rail 266. In some embodiments, the VSS power pickup cells 264a and 264b are VB type power pickup cells or structures.

The device 250 includes the first metallization layer M0 VDD power rail 262 and the first metallization layer M0 VSS power rail 266. The first metallization layer M0 VDD power rail 262 is electrically connected through a first via 268a to a second frontside metallization layer M1270, to a second via 268b, and to a first frontside metallization layer M0 that is a clock cell VDD power rail 272. Also, the first metallization layer M0 VDD power rail 262 is electrically connected through a third via 268c to another second frontside metallization layer M1274, to a fourth via 268d, and to the first frontside metallization layer M0 that is the clock cell VDD power rail 272.

The first metallization layer M0 VSS power rail 266 is electrically connected through a fifth via 268e to a second frontside metallization layer M1276, to a sixth via 268f, and to a first frontside metallization layer M0 that is a clock cell VSS power rail 278. The first metallization layer M0 VSS power rail 266 is electrically connected through a seventh via 268g to a second frontside metallization layer M1280, to an eighth via 268h, and to the first frontside metallization layer M0 that is the clock cell VSS power rail 278.

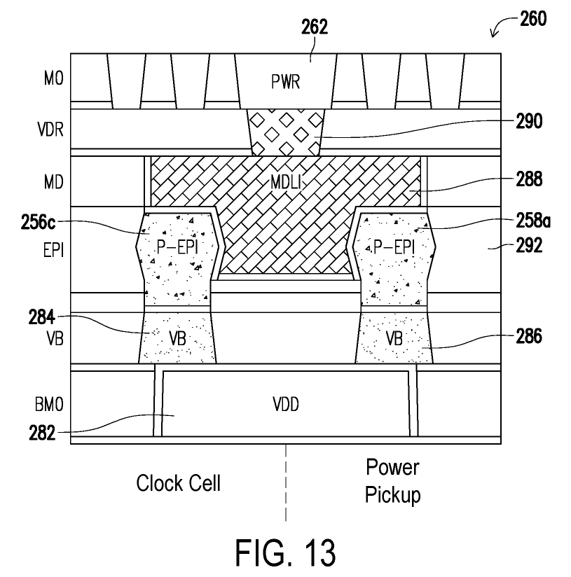

FIG. 13 is a diagram schematically illustrating a cross-section of the VDD power pickup cell 260 taken along the line B-B in FIG. 12, in accordance with some embodiments. The VDD power pickup cell 260 includes a first backside metallization layer BM0282, a first VB 284, a second VB 286, the clock cell P-type epitaxial active region 256c, the power pickup cell P-type epitaxial active region 258a, an MD layer 288 (also shown in FIG. 12), a VDR 290 (also shown in FIG. 12), and the first metallization layer M0 VDD power rail 262.

The VDD power pickup cell 260 passes through an N or P well active region 292 of the device 250 to deliver the power source voltage VDD from the back side of the device 250 to the front side of the device 250. The first backside metallization layer BM0282 of the VDD power pickup cell 260 is electrically connected to the first VB 284 that is electrically connected to the clock cell P-type epitaxial active region 256c and to the second VB 286 that is electrically connected to the power pickup cell P-type epitaxial active region 258a. The clock cell P-type epitaxial active region 256c and the power pickup cell P-type epitaxial active region 258a are electrically connected to the MD layer 288 that is electrically connected to the VDR 290 that is electrically connected to the first metallization layer M0 VDD power rail 262.

The power source voltage VDD flows from the first backside metallization layer BM0282 to the first VB 284 and the clock cell P-type epitaxial active region 256c and to the second VB 286 and the power pickup cell P-type epitaxial active region 258a. Then the power source voltage VDD flows from the clock cell P-type epitaxial active region 256c and the power pickup cell P-type epitaxial active region 258a to the MD layer 288, the VDR 290, and the first metallization layer M0 VDD power rail 262 and, in some embodiments, to a VDD distribution network. Thus, the power source voltage VDD is delivered through the VDD power pickup cell 260 from the first backside metallization layer BM0282 to the clock cell 252 and the power pickup cells 254.

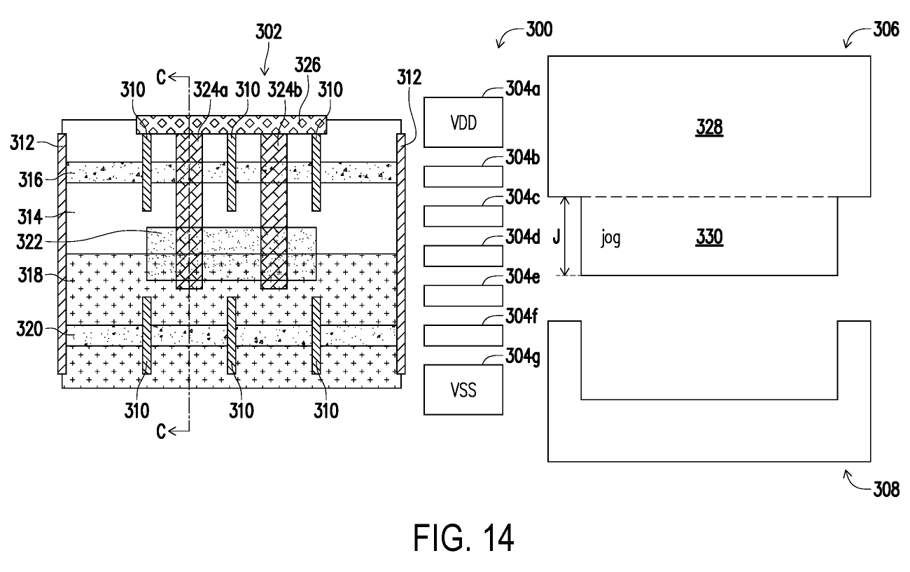

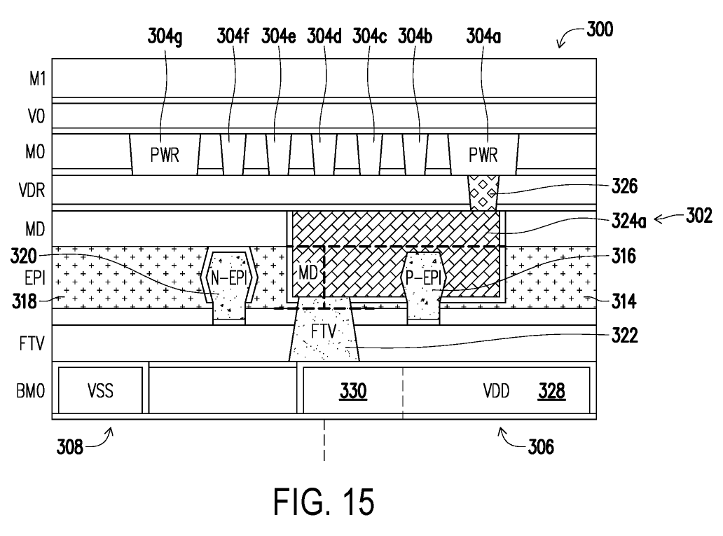

FIGS. 14 and 15 are diagrams schematically illustrating a device 300 that includes an FTV type power pickup cell or structure 302 for delivering power source voltage VDD from the back side of the device 300 to the front side of the device 300. In some embodiments, the device 300 is like the device 40 of FIG. 1.

FIG. 14 is a diagram schematically illustrating the device 300 that includes the FTV power pickup structure 302, first frontside metallization layers M0304a-304g, and first backside metallization layers BM0306 and 308 for delivering power source voltage VDD, in accordance with some embodiments. The first frontside metallization layers M0304a-304g are above or on top of the FTV power pickup structure 302, and the first backside metallization layers BM0306 and 308 are below or underneath the FTV power pickup structure 302. The power distribution networks in the first frontside metallization layers M0304a-304g are different for the power source VDD and the power source VSS. Also, the device 300 includes gate contacts 310, such as PO gates or lines, and edge fingers 312, such as edge PO fingers. The first frontside metallization layers M0304a-304g and the first backside metallization layers BM0 306 and 308 are drawn separately for clarity.

The device 300 includes an N-type well active region 314 with a P-type epitaxial layer active region 316, and a P-type well active region 318 with an N-type epitaxial layer active region 320. The FTV power pickup structure 302 passes through the N-type well active region 314 and the P-type well active region 318 for the power source voltage VDD.

The FTV power pickup structure 302 includes an FTV contact 322, MD contacts 324a and 324b, and a VDR contact 326. The first backside metallization layer BM0306 includes a base portion 328 and an extension or jog 330 that extends away from the base portion 328 and under the FTV contact 322. The height of the jog 330 is referred to as jog distance J. The first backside metallization layer BM0308 is recessed or indented to avoid interference between the first backside metallization layer BM0306 and the first backside metallization layer BM0308. The extension or jog 330 of the first backside metallization layer BM0306 is electrically connected to and delivers power source VDD to the FTV contact 322 that is electrically connected to the MD contacts 324a and 324b that are electrically connected to the VDR contact 326 that is electrically connected to the first frontside metallization layer M0304a for the power source VDD.

FIG. 15 is a diagram schematically illustrating a cross-section of the device 300 taken along the line C-C in FIG. 14, in accordance with some embodiments. The device 300 includes the first frontside metallization layers M0304a-304g above or on top of the FTV power pickup structure 302, and the first backside metallization layers BM0 306 and 308 below or underneath the FTV power pickup structure 302.

The FTV power pickup structure 302 passes through the N-type well active region 314 and the P-type well active region 318. The FTV power pickup structure 302 includes the FTV contact 322, the MD contacts 324a and 324b, and the VDR contact 326. The extension or jog 330 of the first backside metallization layer BM0306 is electrically connected to and delivers power source VDD to the FTV contact 322 that is electrically connected to the MD contact 324a (and to the MD contact 324b) that are electrically connected to the VDR contact 326 that is electrically connected to the first frontside metallization layer M0304a for the power source VDD. Also, the MD contact 324a is electrically connected to the P-type epitaxial layer active region 316. The power source voltage VDD flows from the first backside metallization layer BM0306 to the FTV contact 322, to the MD contact 324a (and the MD contact 324b), to the VDR contact 326, and to the first frontside metallization layer M0304a and, in some embodiments, to a VDD distribution network.

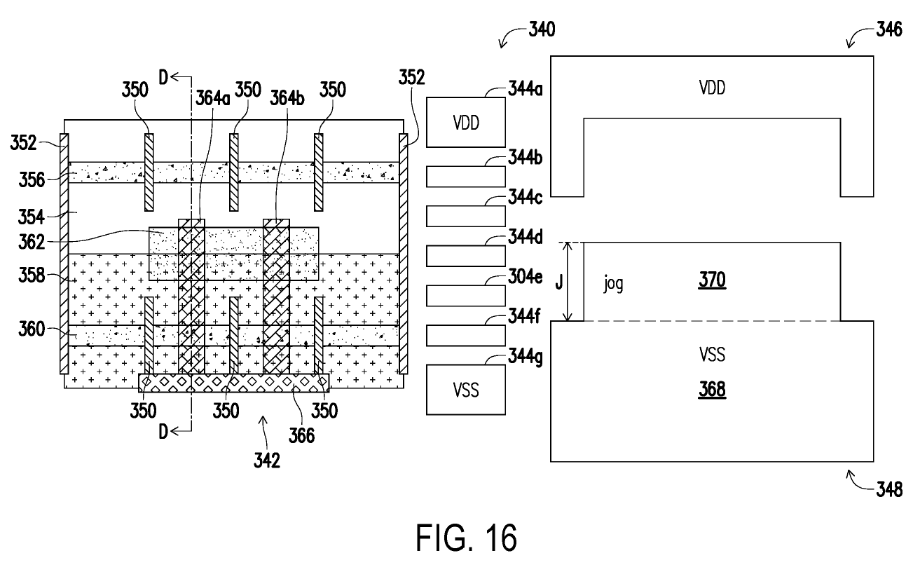

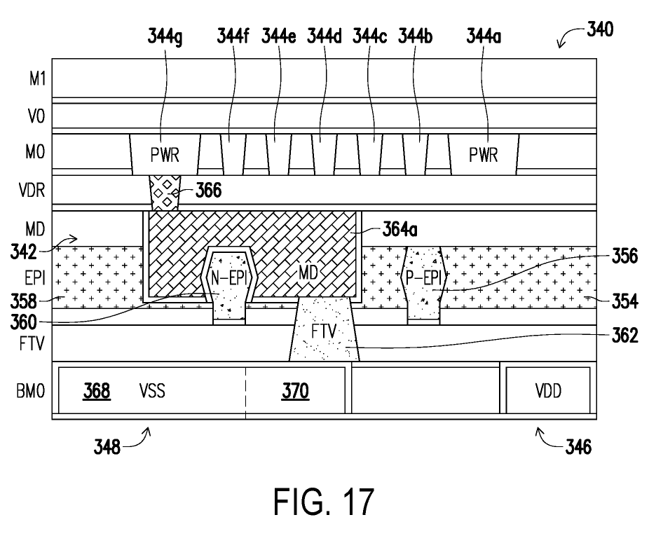

FIGS. 16 and 17 are diagrams schematically illustrating a device 340 that includes an FTV type power pickup cell or structure 342 for delivering power source voltage VSS from the back side of the device 340 to the front side of the device 340. In some embodiments, the device 340 is like the device 40 of FIG. 1.

FIG. 16 is a diagram schematically illustrating the device 340 that includes the FTV power pickup structure 342, first frontside metallization layers M0344a-344g, and first backside metallization layers BM0346 and 348 for delivering power source voltage VSS, in accordance with some embodiments. The first frontside metallization layers M0344a-344g are above or on top of the FTV power pickup structure 342, and the first backside metallization layers BM0346 and 348 are below or underneath the FTV power pickup structure 342. The power distribution networks in the first frontside metallization layers M0344a-344g are different for the power source VDD and the power source VSS. Also, the device 340 includes gate contacts 350, such as PO gates or lines, and edge fingers 352, such as edge PO fingers. The first frontside metallization layers M0344a-344g and the first backside metallization layers BM0346 and 348 are drawn separately for clarity.

The device 340 includes an N-type well active region 354 with a P-type epitaxial layer active region 356, and a P-type well active region 358 with an N-type epitaxial layer active region 360. The FTV power pickup structure 342 passes through the N-type well active region 354 and the P-type well active region 358 for the power source voltage VSS.

The FTV power pickup structure 342 includes an FTV contact 362, MD contacts 364a and 364b, and a VDR contact 366. The first backside metallization layer BM0 348 includes a base portion 368 and an extension or jog 370 that extends away from the base portion 368 and under the FTV contact 362. The height of the jog 370 is referred to as jog distance J. The first backside metallization layer BM0346 is recessed or indented to avoid interference between the first backside metallization layer BM0346 and the first backside metallization layer BM0348. The extension or jog 370 of the first backside metallization layer BM0348 is electrically connected to and delivers power source voltage VSS to the FTV contact 362 that is electrically connected to the MD contacts 364a and 364b that are electrically connected to the VDR contact 366 that is electrically connected to the first frontside metallization layer M0344g for the power source VSS.

FIG. 17 is a diagram schematically illustrating a cross-section of the device 340 taken along the line D-D in FIG. 16, in accordance with some embodiments. The device 340 includes the first frontside metallization layers M0344a-344g above or on top of the FTV power pickup structure 342, and the first backside metallization layers BM0 346 and 348 below or underneath the FTV power pickup structure 342.

The FTV power pickup structure 342 passes through the N-type well active region 354 and the P-type well active region 358. The FTV power pickup structure 342 includes the FTV contact 362, the MD contacts 364a and 364b, and the VDR contact 366. The extension or jog 370 of the first backside metallization layer BM0348 is electrically connected to and delivers power source VSS to the FTV contact 362 that is electrically connected to the MD contact 364a (and to the MD contact 364b) that are electrically connected to the VDR contact 366 that is electrically connected to the first frontside metallization layer M0344g for the power source VSS. Also, the MD contact 364a is electrically connected to the N-type epitaxial layer active region 360. The power source voltage VSS flows from the first backside metallization layer BM0348 to the FTV contact 362, to the MD contact 364a (and the MD contact 364b), to the VDR contact 366, and to the first frontside metallization layer M0344g and, in some embodiments, to a VSS distribution network.

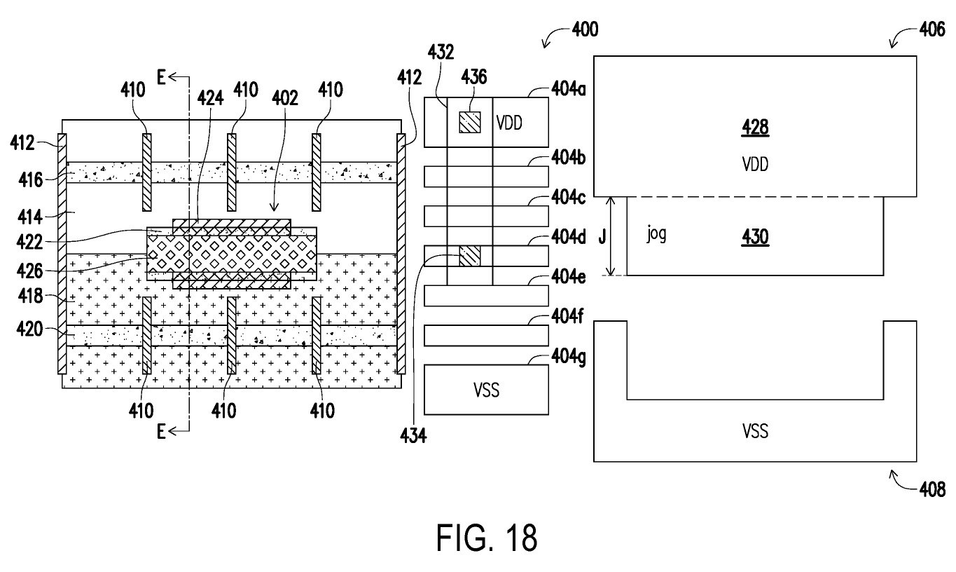

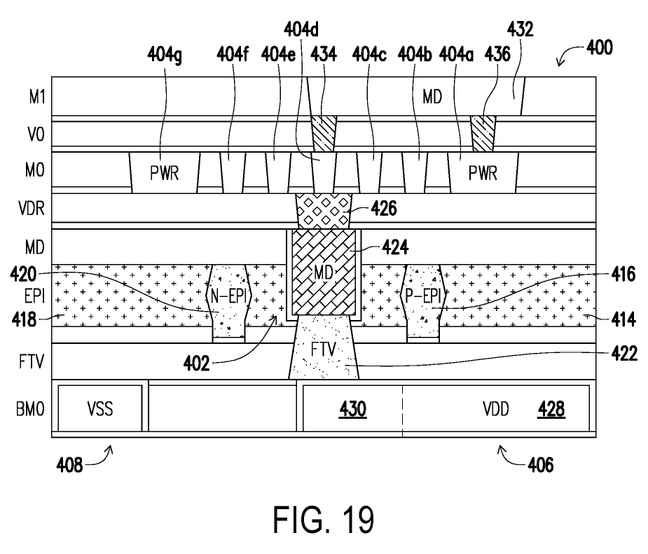

FIGS. 18 and 19 are diagrams schematically illustrating a device 400 that includes an FTV type power pickup cell or structure 402 for delivering power source voltage VDD from the back side of the device 400 to the front side of the device 400. The FTV type power pickup structure 402 is situated in the central area of the device 400 and a protrusion or jog 430 of the first backside metallization layer BM0406 is extended to the central area to contact the FTV type power pickup structure 402. Also, a recess or indentation in the first backside metallization layer BM0408 corresponds to the jog 430 to avoid interference between the first backside metallization layer BM0 406 and the first backside metallization layer BM0408. The height of the jog 430 is referred to as jog distance J. In some embodiments, the device 400 is referred to as a power pickup cell. In some embodiments, the device 400 is like the device 40 of FIG. 1.

FIG. 18 is a diagram schematically illustrating the device 400 that includes the FTV power pickup structure 402, first frontside metallization layers M0404a-404g, and first backside metallization layers BM0406 and 408 for delivering power source voltage VDD, in accordance with some embodiments. The first frontside metallization layers M0404a-404g are above or on top of the FTV power pickup structure 402, and the first backside metallization layers BM0 406 and 408 are below or underneath the FTV power pickup structure 402. The power distribution networks in the first frontside metallization layers M0404a-404g are different for the power source VDD and the power source VSS. Also, the device 400 includes gate contacts 410, such as PO gates or lines, and edge fingers 412, such as edge PO fingers. The first frontside metallization layers M0404a-404g and the first backside metallization layers BM0406 and 408 are drawn separately for clarity.

The device 400 includes an N-type well active region 414 with a P-type epitaxial layer active region 416, and a P-type well active region 418 with an N-type epitaxial layer active region 420. The FTV power pickup structure 402 passes through the N-type well active region 414 and the P-type well active region 418 for the power source voltage VDD.

The FTV power pickup structure 402 includes an FTV contact 422, an MD contact 424, and a VDR contact 426. The first backside metallization layer BM0406 includes a base portion 428 and a protrusion (extension) or jog 430 that extends away from the base portion 428 and under the FTV contact 422. The first backside metallization layer BM0 408 is recessed or indented to avoid interference between the first backside metallization layer BM0406 and the first backside metallization layer BM0 408. The jog 430 of the first backside metallization layer BM0406 is electrically connected to and delivers power source VDD to the FTV contact 422 that is electrically connected to the MD contact 424 that is electrically connected to the VDR contact 426 that is electrically connected to the first frontside metallization layer M0404d for the power source VDD. The first frontside metallization layer M0404d is electrically connected to a second frontside metallization layer M1432 through a first via 434 and the second frontside metallization layer M1432 is electrically connected to the first frontside metallization layer M0404a through a second via 436. In some embodiments, the first frontside metallization layer M0404a is connected to a VDD PDN.

FIG. 19 is a diagram schematically illustrating a cross-section of the device 400 taken along the line E-E in FIG. 18, in accordance with some embodiments. The device 400 includes the first frontside metallization layers M0404a-404g above or on top of the FTV power pickup structure 402, and the first backside metallization layers BM0406 and 408 below or underneath the FTV power pickup structure 402. Also, the second frontside metallization layer M1432 is above or on top of the first frontside metallization layers M0404a-404g.

The FTV power pickup structure 402 passes through the N-type well active region 414 and the P-type well active region 418. The FTV power pickup structure 402 includes the FTV contact 422, the MD contact 424, and the VDR contact 426. The extension or jog 430 of the first backside metallization layer BM0 406 is electrically connected to and delivers power source VDD to the FTV contact 422 that is electrically connected to the MD contact 424 that is electrically connected to the VDR contact 426 that is electrically connected to the first frontside metallization layer M0404d that is electrically connected to the second frontside metallization layer M1432 through the first via 434 and the second frontside metallization layer M1432 is electrically connected to the first frontside metallization layer M0404a through the second via 436 for the power source VDD.

The power source voltage VDD flows from the first backside metallization layer BM0406 to the FTV contact 422, to the MD contact 424, to the VDR contact 426, to the first frontside metallization layer M0404d, to the first via 434, to the second frontside metallization layer M1432, to the second via 436, and to the first frontside metallization layer M0404a and, in some embodiments, to a VDD distribution network.

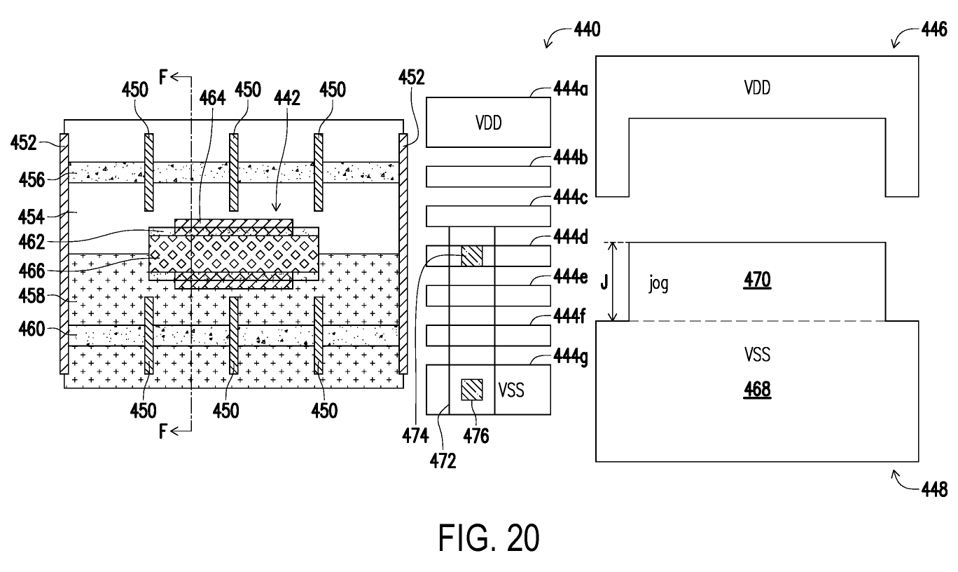

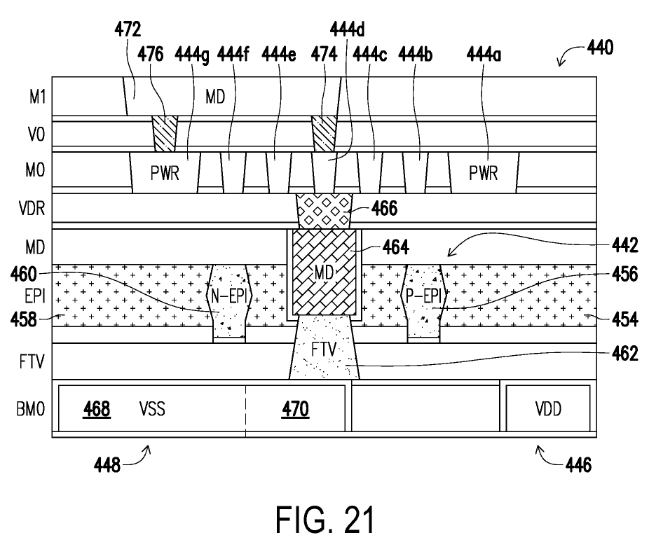

FIGS. 20 and 21 are diagrams schematically illustrating a device 440 that includes an FTV type power pickup cell or structure 442 for delivering power source voltage VSS from the back side of the device 440 to the front side of the device 440. The FTV type power pickup structure 442 is situated in the central area of the device 440 and a protrusion or jog 470 of the first backside metallization layer BM0448 is extended to the central area to contact the FTV type power pickup structure 442. Also, a recess or indentation in the first backside metallization layer BM0 446 corresponds to the jog 470 to avoid interference between the first backside metallization layer BM0 446 and the first backside metallization layer BM0448. The height of the jog 470 is referred to as jog distance J. In some embodiments, the device 440 is referred to as a power pickup cell. In some embodiments, the device 440 is like the device 40 of FIG. 1.

FIG. 20 is a diagram schematically illustrating the device 440 that includes the FTV power pickup structure 442, first frontside metallization layers M0444a-444g, and first backside metallization layers BM0446 and 448 for delivering power source voltage VSS, in accordance with some embodiments. The first frontside metallization layers M0444a-444g are above or on top of the FTV power pickup structure 442, and the first backside metallization layers BM0446 and 448 are below or underneath the FTV power pickup structure 442. The power distribution networks in the first frontside metallization layers M0444a-444g are different for the power source VDD and the power source VSS. Also, the device 440 includes gate contacts 450, such as PO gates or lines, and edge fingers 452, such as edge PO fingers. The first frontside metallization layers M0444a-444g and the first backside metallization layers BM0446 and 448 are drawn separately for clarity.

The device 440 includes an N-type well active region 454 with a P-type epitaxial layer active region 456, and a P-type well active region 458 with an N-type epitaxial layer active region 460. The FTV power pickup structure 442 passes through the N-type well active region 454 and the P-type well active region 458 for the power source voltage VSS.

The FTV power pickup structure 442 includes an FTV contact 462, an MD contact 464, and a VDR contact 466. The first backside metallization layer BM0448 includes a base portion 468 and a protrusion (extension) or jog 470 that extends away from the base portion 468 and under the FTV contact 462. The first backside metallization layer BM0 446 is recessed or indented to avoid interference between the first backside metallization layer BM0446 and the first backside metallization layer BM0 448. The jog 470 of the first backside metallization layer BM0448 is electrically connected to and delivers power source VSS to the FTV contact 462 that is electrically connected to the MD contact 464 that is electrically connected to the VDR contact 466 that is electrically connected to the first frontside metallization layer M0444d for the power source VSS. The first frontside metallization layer M0444d is electrically connected to a second frontside metallization layer M1472 through a first via 474 and the second frontside metallization layer M1472 is electrically connected to the first frontside metallization layer M0444g through a second via 476. In some embodiments, the first frontside metallization layer M0444g is connected to a VSS PDN.

FIG. 21 is a diagram schematically illustrating a cross-section of the device 440 taken along the line F-F in FIG. 20, in accordance with some embodiments. The device 440 includes the first frontside metallization layers M0444a-444g above or on top of the FTV power pickup structure 442, and the first backside metallization layers BM0446 and 448 below or underneath the FTV power pickup structure 442. Also, the second frontside metallization layer M1472 is above or on top of the first frontside metallization layers M0444a-444g.

The FTV power pickup structure 442 passes through the N-type well active region 454 and the P-type well active region 458. The FTV power pickup structure 442 includes the FTV contact 462, the MD contact 464, and the VDR contact 466. The extension or jog 470 of the first backside metallization layer BM0448 is electrically connected to and delivers power source VSS to the FTV contact 462 that is electrically connected to the MD contact 464 that is electrically connected to the VDR contact 466 that is electrically connected to the first frontside metallization layer M0444d that is electrically connected to the second frontside metallization layer M1472 through the first via 474 and the second frontside metallization layer M1472 is electrically connected to the first frontside metallization layer M0444g through the second via 476 for the power source VSS.

The power source voltage VSS flows from the first backside metallization layer BM0448 to the FTV contact 462, to the MD contact 464, to the VDR contact 466, to the first frontside metallization layer M0444d, to the first via 474, to the second frontside metallization layer M1472, to the second via 476, and to the first frontside metallization layer M0444g and, in some embodiments, to a VSS distribution network.

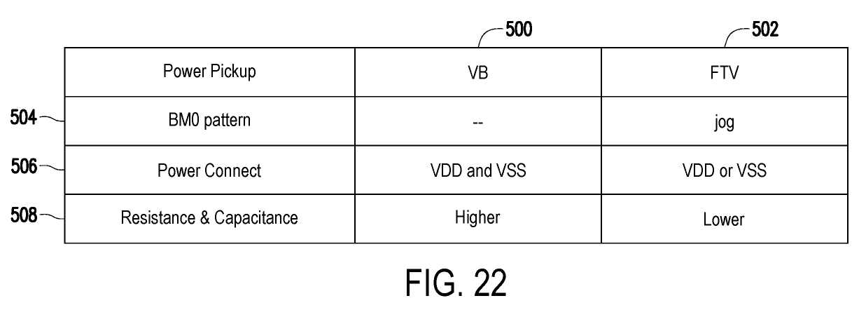

FIG. 22 is a diagram illustrating characteristics for a VB type power pickup cell in column 500 and an FTV type power pickup cell in column 502, in accordance with some embodiments. The power pickup cell characteristics include a first backside metallization layer BM0 pattern in row 504, power source connected in row 506, and resistance and capacitance in row 508.

The first backside metallization layer BM0 pattern in row 504 for the VB type power pickup cell in column 500 does not have an extension or jog for connecting to the power pickup cell. While the first backside metallization layer BM0 pattern in row 504 for the FTV type power pickup cell in column 502 has an extension or jog for connecting to the power pickup cell.

The power source connected in row 506 for the VB type power pickup cell in column 500 is VDD and/or VSS, while the power source connected in row 506 for the FTV type power pickup cell in column 502 is VDD or VSS.

The resistance and capacitance in row 508 for the VB type power pickup cell in column 500 is higher and the resistance and capacitance in row 508 for the FTV type power pickup cell in column 502 is lower.

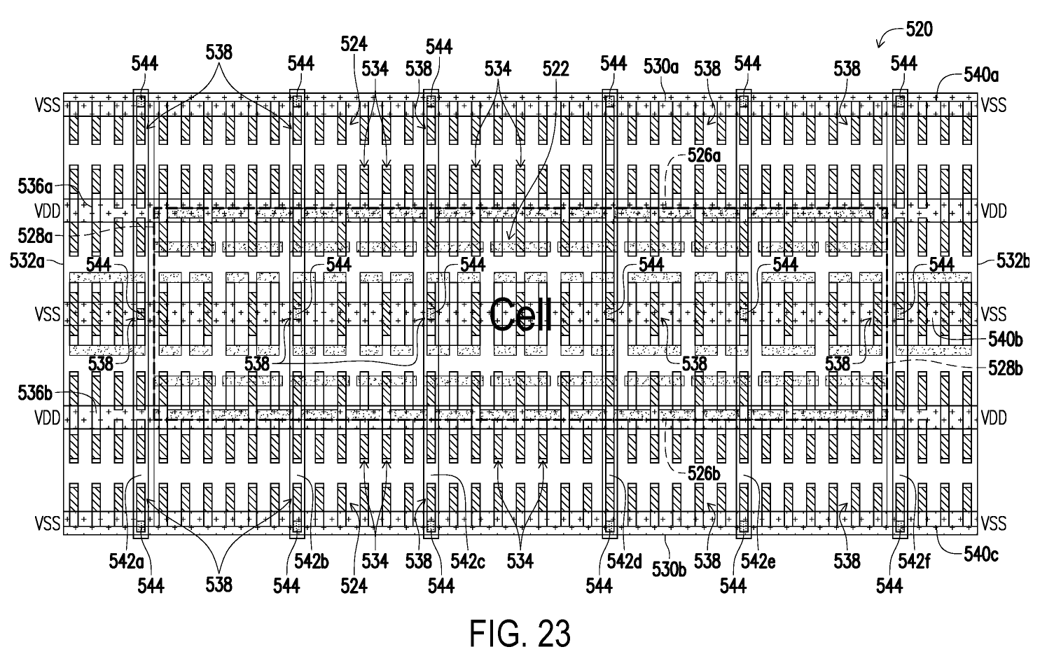

FIG. 23 is a diagram schematically illustrating a device 520 that includes a clock cell 522 and a power pickup cell 524 that surrounds the clock cell 522 on all sides of the clock cell 522, in accordance with some embodiments. The power pickup cell 524 is embedded in the device 520 and the clock cell 522 is situated on a front side of the device 520. In some embodiments, the device 520 is like the device 40 of FIG. 1. In some embodiments, the clock cell 522 is like the electrical circuit 42 (shown in FIG. 1). In some embodiments, the power pickup cell 524 is like the power pickup cell 44 (shown in FIG. 1). In some embodiments, the clock cell 522 is like the clock cell 140 (shown in FIG. 7). In some embodiments, the power pickup cell 524 is like the power pickup cell 142 (shown in FIG. 7).

The clock cell 522 includes two long sides 526a and 526b and two short sides 528a and 528b, and the power pickup cell 524 includes two long sides 530a and 530b and two short sides 532a and 532b. The power pickup cell 524 is configured to deliver one or more voltages, such as power source voltages VDD and VSS, from the back side of the device 520 to the front side of the device 520.

The power pickup cell 524 includes multiple VDD power pickup structures 534 that deliver power source voltage VDD from the back of the device 520 to the front of the device 520. The multiple VDD power pickup structures 534 deliver power source voltage VDD to the VDD power rails 536a and 536b that are on the two opposite or opposing long sides 526a and 526b of the clock cell 522. The VDD power pickup structures 534 deliver power source voltage VDD to the first metallization layer M0 that is the VDD power rail 536a and to the first metallization layer M0 that is the VDD power rail 536b. In some embodiments, each of the VDD power pickup structures 534 is like the VDD power pickup cell 260 that delivers power source voltage VDD from the back side of the device 250 to the front side of the device 250 and to the clock cell 252 as shown in and described in relation to FIGS. 12 and 13.

The power pickup cell 524 includes multiple VSS power pickup structures 538 that deliver power source voltage VSS from the back of the device 520 to the front of the device 520. The multiple VSS power pickup structures 538 deliver power source voltage VSS to the VSS power rails 540a-540c that are on the two opposite or opposing long sides 530a and 530b of the power pickup cell 524 and in a central location of the device 520. The VSS power pickup structures 538 deliver power source voltage VSS to a first metallization layer M0 that is the M0 VSS power rail 540a, to a first metallization layer M0 that is the M0 VSS power rail 540b, and to a first metallization layer M0 that is the M0 VSS power rail 540c. The M0 VSS power rails 540a-540c are electrically connected to each other through second metallization layers M1 that are M1 VSS power rails 542a-542f. Where, the M1 VSS power rails 542a-542f are electrically connected to the M0 VSS power rails 540a-540c through vias 544. In some embodiments, each of the VSS power pickup structures 538 is like one or more of the VB type power pickup structures 220a-220f that deliver the power source voltage VSS from the back side of the device 200 to the front side of the device 200 as shown in and described in relation to FIGS. 9-11.

The power pickup cell 524 reduces wire lengths from the power sources VDD and VSS to the clock cell 522. Also, the power pickup cell 524 reduces IR voltage drops from the power sources VDD and VSS to the clock cell 522 and improves routing resources.

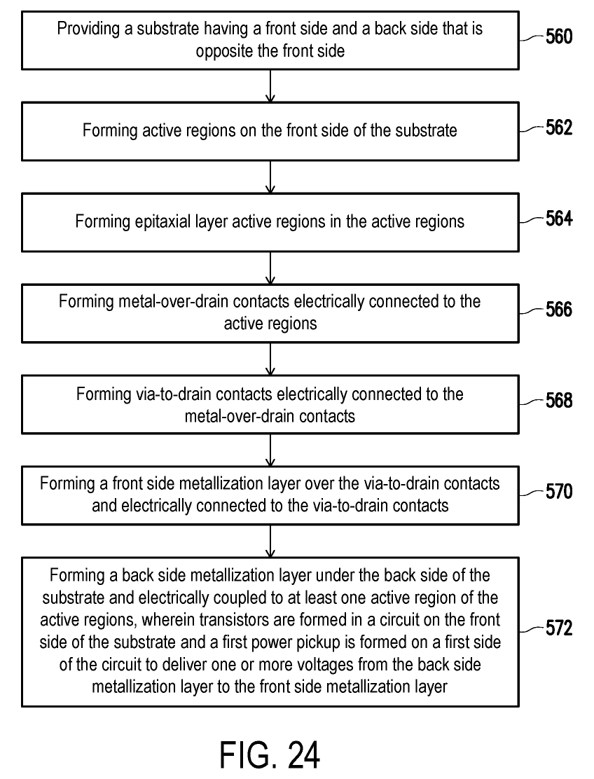

FIG. 24 is a diagram schematically illustrating a method of manufacturing an integrated circuit, in accordance with some embodiments. At step 560, the method includes providing a substrate having a front side and a back side that is opposite the front side. In some embodiments, the substrate is like substrate 202 (shown in FIG. 9).

At step 562, the method includes forming active regions on the front side of the substrate and, at step 564, the method includes forming epitaxial layer active regions in the active regions. In some embodiments, the active regions are N-type well active regions and P-type well active regions. In some embodiments, the active regions are like well active regions 204 and 206 (shown in FIG. 11), 292 (shown in FIG. 13), 314 and 318 (shown in FIG. 15), 354 and 358 (shown in FIG. 17), 414 and 418 (shown in FIG. 19), and 454 and 458 (shown in FIG. 21). In some embodiments, the epitaxial layer active regions are like N-epi or P-epi active regions, such as active regions 230 and 236 (shown in FIG. 11), 256c and 258a (shown in FIG. 13), 316 and 320 (shown in FIG. 15), 356 and 360 (shown in FIG. 17), 416 and 420 (shown in FIG. 19), and 456 and 460 (shown in FIG. 21).

At step 566, the method includes forming MD contacts electrically connected to the active regions and, at step 568, the method includes forming VDR contacts electrically connected to the MD contacts. In some embodiments, the MD contacts are like MD contacts 232b and 232e (shown in FIG. 11), 288 (shown in FIG. 13), 324a (shown in FIG. 15), 364a (shown in FIG. 17), 424 (shown in FIG. 19), and 464 (shown in FIG. 21). In some embodiments, the VDR contacts are like VDR contacts 234 and 238 (shown in FIG. 11), 290 (shown in FIG. 13), 326 (shown in FIG. 15), 366 (shown in FIG. 17), 426 (shown in FIG. 19), and 466 (shown in FIG. 21).

At step 570, the method includes forming a front side metallization layer over the VDR contacts and electrically connected to the VDR contacts, and at step 572, the method includes forming a back side metallization layer under the back side of the substrate and electrically coupled to at least one active region of the active regions. Wherein, transistors are formed in a circuit on the front side of the substrate and a first power pickup is formed on a first side of the circuit to deliver one or more voltages from the back side metallization layer to the front side metallization layer. In some embodiments, the front side metallization layer is like the front side metallization layers 222a-222g (shown in FIG. 11), 262 (shown in FIG. 13), 304a-304g (shown in FIG. 15), 344a-344g (shown in FIG. 17), 404a-404g (shown in FIG. 19), and 444a-444g (shown in FIG. 21). In some embodiments, the back side metallization layer is like the back side metallization layers 208 and 210 (shown in FIG. 11), 282 (shown in FIG. 13), 306 and 308 (shown in FIG. 15), 346 and 348 (shown in FIG. 17), 406 and 408 (shown in FIG. 19), and 446 and 448 (shown in FIG. 21).

In some embodiments, the first power pickup is like the power pickup cell 220 (shown in FIG. 11), 260 (shown in FIG. 13), 302 (shown in FIG. 15), 342 (shown in FIG. 17), 402 (shown in FIG. 19), and/or 442 (shown in FIG. 21). In some embodiments, the circuit is like the electrical circuit 42 (shown in FIG. 1 ,) and/or the clock cell 252 (shown in FIG. 12).

In some embodiments, the method includes forming a second power pickup on a second side of the circuit that is opposite the first side of the circuit to deliver the one or more voltages from the back side metallization layer to the front side metallization layer.

In some embodiments, the method includes forming a VB contact electrically connected to at least one of the epitaxial layer active regions, wherein forming the back side metallization layer includes electrically connecting the back side metallization layer to the VB contact.

In some embodiments, the method includes forming an FTV electrically connected to at least one of the MD contacts, wherein forming the back side metallization layer includes electrically connecting the back side metallization layer to the FTV. In some embodiments, the method includes forming a back side metallization layer that includes a jog extension for electrically connecting to the FTV.

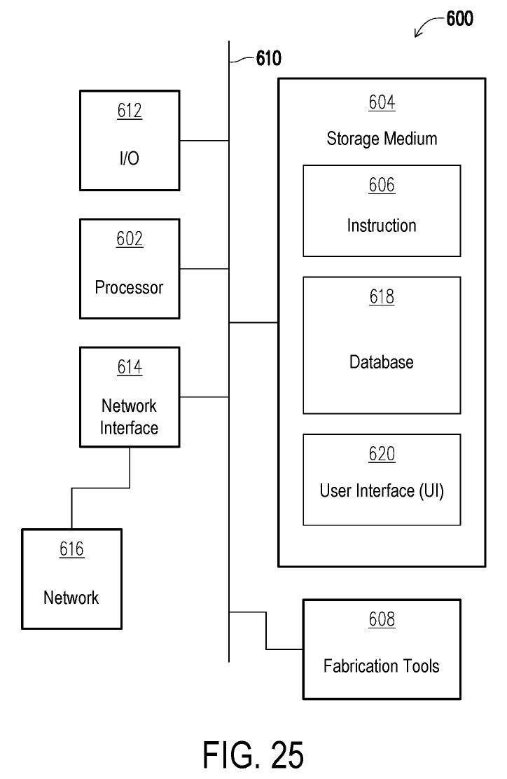

FIG. 25 is a block diagram schematically illustrating an example of a computer system 600 configured to provide the devices, including electronic devices and semiconductor devices, and methods of the current disclosure, in accordance with some embodiments. Some or all the design, layout, and manufacture of the semiconductor devices, also referred to as semiconductor circuits, can be performed by or with the aid of the computer system 600. Also, some or all the design, layout, and manufacture of the devices including electronic devices can be performed by or with the aid of the computer system 600. In some embodiments, the computer system 600 includes an electronic design automation (EDA) system. In some embodiments, the semiconductor devices are ICs.

In some embodiments, the system 600 is a general-purpose computing device including a processor 602 and a non-transitory, computer-readable storage medium 604. The computer-readable storage medium 604 may be encoded with, e.g., store, computer program code such as executable instructions 606. Execution of the instructions 606 by the processor 602 provides (at least in part) a design tool that implements a portion or all the functions of the system 600, such as pre-layout simulations, post-layout simulations, routing, rerouting, and final layout for manufacturing. Further, fabrication tools 608 are included to further layout and physically implement the design and manufacture of the semiconductor devices. In some embodiments, execution of the instructions 606 by the processor 602 provides (at least in part) a design tool that implements a portion or all the functions of the system 600. In some embodiments, the system 600 includes a commercial router. In some embodiments, the system 600 includes an automatic place and route (APR) system.

The processor 602 is electrically coupled to the computer-readable storage medium 604 by a bus 610 and to an I/O interface 612 by the bus 610. A network interface 614 is also electrically connected to the processor 602 by the bus 610. The network interface 614 is connected to a network 616, so that the processor 602 and the computer-readable storage medium 604 can connect to external elements using the network 616. The processor 602 is configured to execute the computer program code or instructions 606 encoded in the computer-readable storage medium 604 to cause the system 600 to perform a portion or all the functions of the system 600, such as providing the semiconductor devices and methods of the current disclosure and other functions of the system 600. In some embodiments, the processor 602 is a central processing unit (CPU), a multi-processor, a distributed processing system, an application specific integrated circuit (ASIC), and/or a suitable processing unit.

In some embodiments, the computer-readable storage medium 604 is an electronic, magnetic, optical, electromagnetic, infrared, and/or semiconductor system or apparatus or device. For example, the computer-readable storage medium 604 can include a semiconductor or solid-state memory, a magnetic tape, a removable computer diskette, a random-access memory (RAM), a read-only memory (ROM), a rigid magnetic disk, and/or an optical disk. In some embodiments using optical disks, the computer-readable storage medium 604 can include a compact disk read only memory (CD-ROM), a compact disk read/write memory (CD-R/W), and/or a digital video disc (DVD).

In some embodiments, the computer-readable storage medium 604 stores computer program code or instructions 606 configured to cause the system 600 to perform a portion or all the functions of the system 600. In some embodiments, the computer-readable storage medium 604 also stores information which facilitates performing a portion or all the functions of the system 600. In some embodiments, the computer-readable storage medium 604 stores a database 618 that includes one or more of component libraries, digital circuit cell libraries, and databases.

The system 600 includes the I/O interface 612, which is coupled to external circuitry. In some embodiments, the I/O interface 612 includes a keyboard, keypad, mouse, trackball, trackpad, touchscreen, and/or cursor direction keys for communicating information and commands to the processor 602.

The network interface 614 is coupled to the processor 602 and allows the system 600 to communicate with the network 616, to which one or more other computer systems are connected. The network interface 614 can include: wireless network interfaces such as BLUETOOTH, WIFI, WIMAX, GPRS, or WCDMA; or wired network interfaces such as ETHERNET, USB, or IEEE-1364. In some embodiments, a portion or all the functions of the system 600 can be performed in two or more systems that are like system 600.

The system 600 is configured to receive information through the I/O interface 612. The information received through the I/O interface 612 includes one or more of instructions, data, design rules, libraries of components and cells, and/or other parameters for processing by the processor 602. The information is transferred to the processor 602 by the bus 610. Also, the system 600 is configured to receive information related to a user interface (UI) through the I/O interface 612. This UI information can be stored in the computer-readable storage medium 604 as a UI 620.

In some embodiments, a portion or all the functions of the system 600 are implemented via a standalone software application for execution by a processor. In some embodiments, a portion or all the functions of the system 600 are implemented in a software application that is a part of an additional software application. In some embodiments, a portion or all the functions of the system 600 are implemented as a plug-in to a software application. In some embodiments, at least one of the functions of the system 600 is implemented as a software application that is a portion of an EDA tool. In some embodiments, a portion or all the functions of the system 600 are implemented as a software application that is used by the system 600. In some embodiments, a layout diagram is generated using a tool such as VIRTUOSO available from CADENCE DESIGN SYSTEMS, Inc., or another suitable layout generating tool.

In some embodiments, the routing, layouts, and other processes are realized as functions of a program stored in a non-transitory computer readable recording medium. Examples of a non-transitory computer readable recording medium include, but are not limited to, external/removable and/or internal/built-in storage or memory units, e.g., one or more optical disks such as a digital video disc or a digital versatile disc (DVD), a magnetic disk such as a hard disk, a semiconductor memory such as a ROM and a RAM, and a memory card, and the like.

As noted above, embodiments of the system 600 include fabrication tools 608 for implementing the manufacturing processes of the system 600. For example, based on the final layout, photolithographic masks may be generated, which are used to fabricate the semiconductor device by the fabrication tools 608.

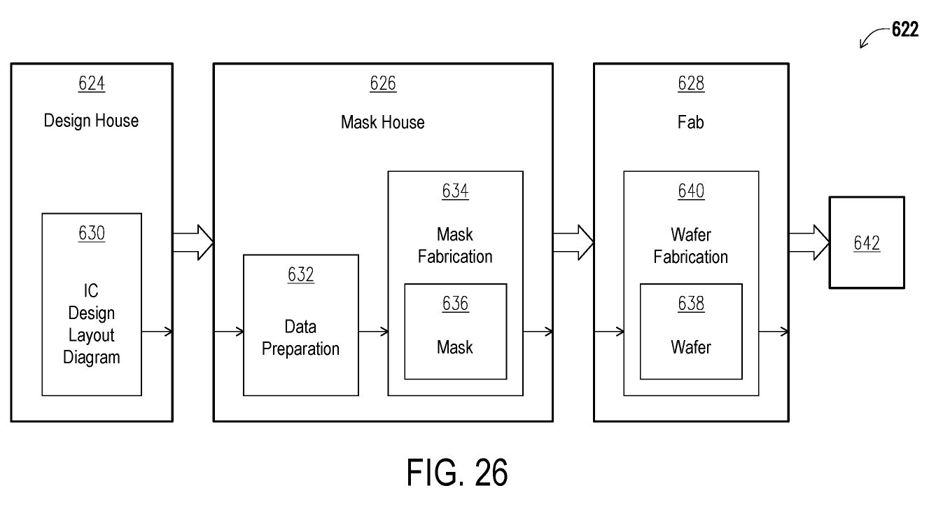

Further aspects of device fabrication are disclosed in conjunction with FIG. 26, which is a block diagram of a semiconductor device manufacturing system 622 and a semiconductor device manufacturing flow associated therewith, in accordance with some embodiments. In some embodiments, based on a layout diagram, one or more semiconductor masks and/or at least one component in a layer of a semiconductor device is fabricated using the manufacturing system 622.

In FIG. 26, the semiconductor device manufacturing system 622 includes entities, such as a design house 624, a mask house 626, and a semiconductor device manufacturer/fabricator (“Fab”) 628, that interact with one another in the design, development, and manufacturing cycles and/or services related to manufacturing a semiconductor device, such as the semiconductor devices described herein. The entities in the system 622 are connected by a communications network. In some embodiments, the communications network is a single network. In some embodiments, the communications network is a variety of different networks, such as an intranet and the internet. The communications network includes wired and/or wireless communication channels. Each entity interacts with one or more of the other entities and provides services to and/or receives services from one or more of the other entities. In some embodiments, two or more of the design house 624, the mask house 626, and the semiconductor device fab 628 are owned by a single larger company. In some embodiments, two or more of the design house 624, the mask house 626, and the semiconductor device fab 628 coexist in a common facility and use common resources.

The design house (or design team) 624 generates a semiconductor device design layout diagram 630. The semiconductor device design layout diagram 630 includes various geometrical patterns, or semiconductor device layout diagrams designed for a semiconductor device. The geometrical patterns correspond to patterns of metal, oxide, or semiconductor layers that make up the various components of the semiconductor structures to be fabricated. The various layers combine to form various semiconductor device features. For example, a portion of the semiconductor device design layout diagram 630 includes various semiconductor device features, such as diagonal vias, active areas or regions, gate electrodes, sources, drains, metal lines, local vias, and openings for bond pads, to be formed in a semiconductor substrate (such as a silicon wafer) and in various material layers disposed on the semiconductor substrate. The design house 624 implements a design procedure to form a semiconductor device design layout diagram 630. The semiconductor device design layout diagram 630 is presented in one or more data files having information of the geometrical patterns. For example, semiconductor device design layout diagram 630 can be expressed in a GDSII file format or DFII file format. In some embodiments, the design procedure includes one or more of analog circuit design, digital circuit design, logic circuit design, standard cell circuit design, power distribution network (PDN) design including power via design, supply voltage track design, reference voltage track design, place and route routines, and physical layout designs.

The mask house 626 includes data preparation 632 and mask fabrication 634. The mask house 626 uses the semiconductor device design layout diagram 630 to manufacture one or more masks 636 to be used for fabricating the various layers of the semiconductor device or semiconductor structure. The mask house 626 performs mask data preparation 632, where the semiconductor device design layout diagram 630 is translated into a representative data file (RDF). The mask data preparation 632 provides the RDF to the mask fabrication 634. The mask fabrication 634 includes a mask writer that converts the RDF to an image on a substrate, such as a mask (reticle) 636 or a semiconductor wafer 638. The design layout diagram 630 is manipulated by the mask data preparation 632 to comply with characteristics of the mask writer and/or criteria of the semiconductor device fab 628. In FIG. 26, the mask data preparation 632 and the mask fabrication 634 are illustrated as separate elements. In some embodiments, the mask data preparation 632 and the mask fabrication 634 can be collectively referred to as mask data preparation.

In some embodiments, the mask data preparation 632 includes an optical proximity correction (OPC) which uses lithography enhancement techniques to compensate for image errors, such as those that can arise from diffraction, interference, other process effects and the like. The OPC adjusts the semiconductor device design layout diagram 630. In some embodiments, the mask data preparation 632 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 632 includes a mask rule checker (MRC) that checks the semiconductor device design layout diagram 630 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the semiconductor device design layout diagram 630 to compensate for limitations during the mask fabrication 634, which may undo part of the modifications performed by OPC to meet mask creation rules.

In some embodiments, the mask data preparation 632 includes lithography process checking (LPC) that simulates processing that will be implemented by the semiconductor device fab 628. LPC simulates this processing based on the semiconductor device design layout diagram 630 to create a simulated manufactured device. The processing parameters in LPC simulation can include parameters associated with various processes of the semiconductor device manufacturing cycle, parameters associated with tools used for manufacturing the semiconductor device, and/or other aspects of the manufacturing process. LPC considers various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are to be repeated to further refine the semiconductor device design layout diagram 630.

The above description of mask data preparation 632 has been simplified for the purposes of clarity. In some embodiments, data preparation 632 includes additional features such as a logic operation (LOP) to modify the semiconductor device design layout diagram 630 according to manufacturing rules. Additionally, the processes applied to the semiconductor device design layout diagram 630 during data preparation 632 may be executed in a variety of different orders.

After the mask data preparation 632 and during the mask fabrication 634, a mask 636 or a group of masks 636 are fabricated based on the modified semiconductor device design layout diagram 630. In some embodiments, the mask fabrication 634 includes performing one or more lithographic exposures based on the semiconductor device design layout diagram 630. In some embodiments, an electron-beam (e-beam) or a mechanism of multiple e-beams is used to form a pattern on a mask (photomask or reticle) 636 based on the modified semiconductor device design layout diagram 630. The mask 636 can be formed in various technologies. In some embodiments, the mask 636 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region, and transmits through the transparent regions. In one example, a binary mask version of the mask 636 includes a transparent substrate (e.g., fused quartz) and an opaque material (e.g., chromium) coated in the opaque regions of the binary mask. In another example, the mask 636 is formed using a phase shift technology. In a phase shift mask (PSM) version of the mask 636, various features in the pattern formed on the phase shift mask are configured to have proper phase difference to enhance the resolution and imaging quality. In various examples, the phase shift mask can be attenuated PSM or alternating PSM. The mask(s) generated by the mask fabrication 634 is used in a variety of processes. For example, such a mask(s) is used in an ion implantation process to form various doped regions in the semiconductor wafer 638, in an etching process to form various etching regions in the semiconductor wafer 638, and/or in other suitable processes.

The semiconductor device fab 628 includes wafer fabrication 640. The semiconductor device fab 628 is a semiconductor device fabrication business that includes one or more manufacturing facilities for the fabrication of a variety of different semiconductor device products. In some embodiments, the semiconductor device fab 628 is a semiconductor foundry. For example, there may be a manufacturing facility for the front end of line (FEOL) fabrication of a plurality of semiconductor device products, while a second manufacturing facility may provide the BEOL fabrication for the interconnection and packaging of the semiconductor device products, and a third manufacturing facility may provide other services for the foundry business.

The semiconductor device fab 628 uses the mask(s) 636 fabricated by the mask house 626 to fabricate the semiconductor structures or semiconductor devices 642 of the current disclosure. Thus, the semiconductor device fab 628 at least indirectly uses the semiconductor device design layout diagram 630 to fabricate the semiconductor structures or semiconductor devices 642 of the current disclosure. Also, the semiconductor wafer 638 includes a silicon substrate or other proper substrate having material layers formed thereon, and the semiconductor wafer 638 further includes one or more of various doped regions, dielectric features, multilevel interconnects, and the like (formed at subsequent manufacturing steps). In some embodiments, the semiconductor wafer 638 is fabricated by the semiconductor device fab 628 using the mask(s) 636 to form the semiconductor structures or semiconductor devices 642 of the current disclosure. In some embodiments, the semiconductor device fabrication includes performing one or more lithographic exposures based at least indirectly on the semiconductor device design layout diagram 630.

Disclosed embodiments thus include different placements of power pickup structures next to a circuit, such as a clock cell, and different types of power pickup structures, such as VB type power pickup structures and FTV type power pickup structures.

Disclosed embodiments include a device that includes a substrate with at least one active region and a circuit situated on the front side of the substrate. A front side metallization layer is disposed over the circuit and a back side metallization layer is disposed under the back side of the substrate. A first power pickup structure is situated on one side of the circuit to deliver one or more voltages from the back side metallization layer to the front side metallization layer and, in some embodiments, a second power pickup structure is situated on another side of the circuit that is opposite the one side of the circuit to deliver the one or more voltages from the back side metallization layer to the front side metallization layer.

In some embodiments, the power pickup structures include a backside metallization layer electrically connected to a VB that is electrically connected to an epitaxial layer that is electrically connected to an MD contact that is electrically connected to a VDR contact that is electrically connected to a front side metallization layer. Such that a power source voltage is conducted from the back side metallization layer to the front side metallization layer through the VB, the epitaxial layer, the MD contact, and the VDR contact.

In some embodiments, the power pickup structure includes an FTV, an MD contact, and a VDR contact, where the back side metallization layer is electrically connected to the FTV that is electrically connected to the MD contact that is electrically connected to the VDR contact that is electrically connected to the front side metallization layer. Such that a power source voltage is conducted from the back side metallization layer to the front side metallization layer through the FTV, the MD contact, and the VDR contact.

Disclosed embodiments further include a method of manufacturing an integrated circuit that includes forming a substrate having a front side and a back side that is opposite the front side; forming active regions on the front side of the substrate; forming a circuit on the front side of the substrate; forming a front side metallization layer over the circuit; forming a back side metallization layer under the back side of the substrate and electrically coupled to at least one active region of the active regions; and forming a power pickup cell on a side of the circuit to deliver one or more voltages from the back side metallization layer to the front side metallization layer.

In accordance with some embodiments, an integrated circuit includes a substrate having a front side and a back side that is opposite the front side. The substrate includes at least one active region on the front side. A circuit is situated on the front side of the substrate and a front side metallization layer is disposed over the circuit. A back side metallization layer is disposed under the back side of the substrate and a first power pickup is situated on a first side of the circuit. The first power pickup is configured to deliver one or more voltages from the back side metallization layer, that is electrically coupled to the at least one active region, to the front side metallization layer.

In accordance with further embodiments, a device includes a substrate having a front side and a back side that is opposite the front side. A circuit is situated on the front side of the substrate and a first front side metallization layer is disposed over the substrate. A back side metallization layer is disposed under the back side of the substrate and a first power pickup is situated on a first side of the circuit. The first power pickup includes an FTV, an MD contact, and a VDR contact that is electrically connected from the back side metallization layer to the first front side metallization layer.

In accordance with still further disclosed aspects, a method of manufacturing an integrated circuit includes providing a substrate having a front side and a back side that is opposite the front side; forming active regions on the front side of the substrate; forming epitaxial layer active regions in the active regions; forming MD contacts electrically connected to the active regions; forming VDR contacts electrically connected to the MD contacts; forming a front side metallization layer over the VDR contacts and electrically connected to the VDR contacts; forming a back side metallization layer under the back side of the substrate and electrically coupled to at least one active region of the active regions, wherein transistors are formed in a circuit on the front side of the substrate and a first power pickup is formed on a first side of the circuit to deliver one or more voltages from the back side metallization layer to the front side metallization layer.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit, comprising:
a substrate having a front side and a back side that is opposite the front side, the substrate includes at least one active region on the front side;
a circuit situated on the front side of the substrate;
a front side metallization layer disposed over the circuit;
a back side metallization layer disposed under the back side of the substrate; and
a first power pickup situated on a first side of the circuit and configured to deliver one or more voltages from the back side metallization layer, that is electrically coupled to the at least one active region, to the front side metallization layer.

2. The integrated circuit of claim 1, comprising a second power pickup situated on a second side of the circuit that is opposite the first side of the circuit and configured to deliver the one or more voltages from the back side metallization layer to the front side metallization layer.

3. The integrated circuit of claim 1, wherein the one or more voltages include a first voltage VDD and a second voltage VSS.

4. The integrated circuit of claim 1, wherein the first side of the circuit is either a longer side or a shorter side in a top view of the integrated circuit.

5. The integrated circuit of claim 1, comprising a first backside via, a P-type epitaxial layer, a first metal-over-drain contact, and a first via-to-drain contact, wherein the back side metallization layer is electrically coupled to the front side metallization layer through the first backside via, the P-type epitaxial layer, the first metal-over-drain contact, and the first via-to-drain contact, such that a first voltage of the one or more voltages is conducted between the back side metallization layer and the front side metallization layer through the first backside via, the P-type epitaxial layer, the first metal-over-drain contact, and the first via-to-drain contact.

6. The integrated circuit of claim 5, comprising a second backside via, an N-type epitaxial layer, a second metal-over-drain contact, and a second via-to-drain contact, wherein the back side metallization layer is electrically coupled to the front side metallization layer through the second backside via, the N-type epitaxial layer, the second metal-over-drain contact, and the second via-to-drain contact, such that a second voltage of the one or more voltages is conducted between the back side metallization layer and the front side metallization layer through the second backside via, the N-type epitaxial layer, the second metal-over-drain contact, and the second via-to-drain contact.

7. The integrated circuit of claim 1, comprising a feed-through via, a metal-over-drain contact, and a via-to-drain contact wherein the back side metallization layer is electrically coupled to the front side metallization layer through the feed-through via, the metal-over-drain contact, and the via-to-drain contact, such that a voltage VDD of the one or more voltages is conducted between the back side metallization layer and the front side metallization layer through the feed-through via, the metal-over-drain contact, and the via-to-drain contact.

8. The integrated circuit of claim 7, wherein the metal-over-drain contact is electrically connected to a P-type epitaxial layer and the back side metallization layer includes a segment that includes a jog for connecting to the feed-through via.

9. The integrated circuit of claim 1, comprising a feed-through via, a metal-over-drain contact, and a via-to-drain contact wherein the back side metallization layer is electrically coupled to the front side metallization layer through the feed-through via, the metal-over-drain contact, and the via-to-drain contact, such that a voltage VSS of the one or more voltages is conducted between the back side metallization layer and the front side metallization layer through the feed-through via, the metal-over-drain contact, and the via-to-drain contact.

10. The integrated circuit of claim 9, wherein the metal-over-drain contact is electrically connected to an N-type epitaxial layer and the back side metallization layer includes a segment that includes a jog for connecting to the feed-through via.

11. A device, comprising:
a substrate having a front side and a back side that is opposite the front side;
a circuit situated on the front side of the substrate;
a first front side metallization layer disposed over the substrate;
a back side metallization layer disposed under the back side of the substrate; and
a first power pickup situated on a first side of the circuit and including a feed-through via, a metal-over-drain contact, and a via-to-drain contact that is electrically connected from the back side metallization layer to the first front side metallization layer.

12. The device of claim 11, comprising a second front side metallization layer disposed over the first front side metallization layer, a first via, and a second via, wherein the first front side metallization layer is electrically connected to the second front side metallization layer through the first via and the second front side metallization layer is electrically connected to a power rail in the first front side metallization layer through the second via.

13. The device of claim 11, wherein the feed-through via, the metal-over-drain contact, and the via-to-drain contact are electrically connected from the back side metallization layer to the first front side metallization layer without being electrically connected to a P-type epitaxial layer or an N-type epitaxial layer.

14. The device of claim 11, wherein the back side metallization layer includes a segment that includes a jog for connecting to the feed-through via.

15. The device of claim 11, comprising a second power pickup situated on a second side of the circuit that is opposite the first side of the circuit and configured to deliver a first voltage VDD or a second voltage VSS from the back side metallization layer to the front side metallization layer.

16. A method of manufacturing an integrated circuit, comprising:
providing a substrate having a front side and a back side that is opposite the front side;
forming active regions on the front side of the substrate;
forming epitaxial layer active regions in the active regions;
forming metal-over-drain contacts electrically connected to the active regions;
forming via-to-drain contacts electrically connected to the metal-over-drain contacts;
forming a front side metallization layer over the via-to-drain contacts and electrically connected to the via-to-drain contacts; and
forming a back side metallization layer under the back side of the substrate and electrically coupled to at least one active region of the active regions, wherein transistors are formed in a circuit on the front side of the substrate and a first power pickup is formed on a first side of the circuit to deliver one or more voltages from the back side metallization layer to the front side metallization layer.

17. The method of claim 16, comprising:
forming a second power pickup on a second side of the circuit that is opposite the first side of the circuit to deliver the one or more voltages from the back side metallization layer to the front side metallization layer.

18. The method of claim 16, comprising:
forming a backside via electrically connected to at least one of the epitaxial layer active regions, wherein forming the back side metallization layer includes electrically connecting the back side metallization layer to the backside via.

19. The method of claim 16, comprising:
forming a feed-through via electrically connected to at least one of the metal-over-drain contacts, wherein forming the back side metallization layer includes electrically connecting the back side metallization layer to the feed-through via.

20. The method of claim 19, wherein forming the back side metallization layer includes forming a back side metallization layer segment that includes a jog extension for electrically connecting to the feed-through via.
